(19) United States
(12) Patent Application Publication
(10) Pub. No.: US 2021/0036250 A1
(43) Pub. Date: Feb. 4, 2021

(54) Cathode Interface Modification Material Composition, Preparation Method and Use Thereof

(71) Applicant: Guizhou Institute of Technology, Guiyang (CN)

(72) Inventors: Menglan LV, Guiyang (CN); Xiwen CHEN, Guiyang (CN); Yongfang LI, Beijing (CN)

(21) Appl. No.: 16/687,332

(22) Filed: Nov. 18, 2019

(30) Foreign Application Priority Data
Aug. 2, 2019 (CN) 201910713309.8

(51) Int. Cl. H01L 51/44; C01B 32/182; C01B 32/159; H01L 51/00

(52) U.S. Cl. CPC H01L 51/441; C01B 32/182; C01B 32/159; H01L 51/0003; H01L 51/0048; H01L 51/0069; H01L 51/0067; H01L 51/0072; H01L 51/0065; H01L 51/0046

(57) ABSTRACT

The present disclosure provides a cathode interface modification material composition, a preparation method and use thereof. In the present disclosure, a uniformly dispersed novel cathode interface modification material composition is obtained by adding a carbon nanomaterial to a cathode interfacial material and dispersing the same in a polar solvent. The cathode interface modification material composition of the present disclosure and the cathode interface modification layer prepared using the cathode interface modification material composition of the present disclosure can be used for the fabrication of various types of organic photoelectric devices.

### CROSS-REFERENCE TO RELATED APPLICATION

The present disclosure claims priority to the Chinese Patent Application with the filing No. 201910713309.8, filed on Aug. 2, 2019 with the State Intellectual Property Office of China, entitled “Cathode Interface Modification Material Composition, Preparation Method and Use Thereof,” the contents of which are incorporated herein by reference in its entirety.

### TECHNICAL FIELD

The present disclosure relates to the technical field of organic photoelectric devices, and particularly to a cathode interface modification material composition containing a carbon nanomaterial and a cathode interfacial material, a preparation method thereof, and use thereof in an organic photoelectric device, and also to a cathode interface modification layer, a preparation method thereof, and use thereof in an organic photoelectric device.

### BACKGROUND ART

Faced with the increasing depletion of fossil energy and its enormous damage to the ecological environment, we must find renewable, cheap, safe and clean energy as an alternative. Therefore, the research on the inexhaustible clean energy, such as solar energy, has been widely concerned by people. In recent years, solar photovoltaic has become one of the most rapidly developed and dynamic research fields. The solar cells studied and developed at present include monocrystalline silicon, polycrystalline silicon, amorphous silicon, thin film semiconductor, dye-sensitized and organic solar cells, etc., among which the first several have been commercialized with a conversion rate of about 18%, but also have the disadvantages of high device fabrication cost, high energy consumption and large pollution in the raw material production process, which greatly restrict the popularization and application thereof. Due to the obvious advantages of low preparation cost, light weight, simple preparation process and ease in the fabrication of large-area flexible devices, etc., organic solar cells have attracted great attention of scientists.

To develop new materials, optimize and promote more efficient device fabrication methods and device structures is a powerful way to obtain highly efficient organic photoelectric devices, wherein interfacial engineering also plays an important role in improving the energy conversion efficiency of photoelectric devices. In the future research work, in order to fabricate devices with high efficiency and good stability, the following several conditions need to be satisfied in the design and development of new interface modification materials: good charge separation performance, the capability of satisfying the compatibility of solubility in the fabrication process of an all-solution processed multi-layer device, and taking into account the integration of an active layer and an interface modification layer.

High-efficient interface modification materials must simultaneously satisfy the requirements about their electronic, optical, chemical and mechanical properties, including the ability to form ohmic contact between the electrode and the active layer, having appropriate energy levels to improve the charge separation on different electrodes, having a relatively wide band gap to limit the diffusion of the photoexciton in the active layer, having relatively low absorption in the near infrared region to minimize light loss, having physical and chemical stability to avoid side effects between the active layer and the electrode, allowing processing in a solution at a relatively low temperature, having relatively strong mechanical properties to enable stable existence in a multi-layer solution processing system, and having excellent film-forming property and a low cost. Therefore, to explore and study new solution-processable interface modification materials so as to realize the fabrication of multi-layer all-solution processed photoelectric devices has attracted a lot of interest from scientists. Moreover, the continuous exploration of the working mechanism of the interface modification materials is also helpful to the study of the internal interface electrical contact of the organic photoelectric devices.

The industrialization of organic solar cells also faces many scientific and technological challenges. In the field of research of organic solar cells, the problems of high-throughput processing and large-area manufacturing must be solved finally. Interfacial engineering is a critical factor in the preparation of high performance, large area, and printable, flexible and low cost organic solar cells. Alcohol-soluble interfacial materials have been widely used in photoelectric devices because of their unique properties and advantages, including the regulation of work function of electrode work, the improvement of charge collection, etc. According to the requirements of the device fabrication process, it is critical to develop a new material with excellent conductivity and charge mobility that can maintain the high energy conversion efficiency of the device under thick film conditions. Moreover, it can provide better technological processing so as to realize better film formation uniformity and excellent surface film forming performance.

In addition, carbon nanomaterials have a high specific surface area, excellent thermal/electrical property, high fluidity of current carrier, transparency, mechanical flexibility, and compatibility with solution treatment, and have been used in the fields of energy, composite materials, electron, etc. Moreover, based on the semi-metal band structure of the continuous adjustable Fermi level, the work function thereof is made to be regulatable in a very wide range. They have relatively high working performance in photovoltaic devices, and have been used in electrode and interfacial materials after improvement. Therefore, the development of effective surfactants and dispersing methods is of great significance for the large-scale production and practical application of carbon nanomaterials.

In view of this, the present disclosure has been proposed.

### SUMMARY

The present disclosure provides a cathode interface modification material composition, comprising:
a) an alcohol solvent;
b) an organic cathode interfacial material, wherein the organic cathode interfacial material is alcohol soluble, wherein the organic cathode interfacial material is dissolved in the alcohol solvent; and
c) a carbon nanomaterial, wherein the carbon nanomaterial is uniformly dispersed in a solution of the organic cathode interfacial material and has a maximum dimension of less than or equal to 5 μm.

The present disclosure provides a method for preparing the above cathode interface modification material composition, comprising ultrasonically treating a solution mixture comprising a carbon nanomaterial, an organic cathode interface modification material and an alcohol solvent, to cause the carbon nanomaterial to be uniformly dispersed in the alcohol solvent to form a suspension.

The present disclosure further provides a cathode interface modification layer, comprising an organic cathode interfacial material and a carbon nanomaterial uniformly dispersed in the organic cathode interfacial material, wherein the carbon nanomaterial has a maximum dimension of less than or equal to 5 μm.

The present disclosure further provides a method for preparing the above cathode interface modification layer, comprising applying the above cathode interface modification material composition to a cathode or an active layer.

The present disclosure further provides an organic photoelectric device, comprising the above cathode interface modification layer.

The present disclosure further provides a method for fabricating the organic photoelectric device, comprising applying the above cathode interface modification material composition to a cathode or an active layer.

The present disclosure further provides use of the above cathode interfacial material composition in the fabrication of an organic photoelectric device.

### BRIEF DESCRIPTION OF DRAWINGS

In order to describe the technical solutions of the embodiments of the present disclosure or in the prior art more clearly, brief description is made below on the drawings required to be used in the description of the embodiments or the prior art. Obviously, the drawings in the following description illustrate some of the embodiments of the present disclosure, and for a person of ordinary skills in the art, other drawings may be obtained from these drawings without inventive effort.

FIGS. 1A, 1B and 1C respectively show the images of the blends of graphene and cathode interfacial materials (PDINO, PDIN and PDI-C) in different solvents prepared according to the method of Comparative example 1, after standing for a period of time (standing for 10 min);

FIG. 2A shows the images of a PDINO-G dispersion liquid (2 mg·mL⁻¹ PDINO, 5% graphene) and a PDINO solution (2 mg·mL⁻¹) prepared by the method of an example of the present disclosure, after standing for a period of time (the solvent being ethanol, and standing for 10 min);

FIG. 2B shows the images of Tyndall effect of a PDINO-G dispersion liquid (1 mg·mL⁻¹ PDINO, 5% graphene) and a PDINO solution (1 mg mL⁻¹) provided by an example of the present disclosure under illumination;

FIG. 3 shows the spectrogram of the X-ray diffraction (XRD) of graphite, PDINO and PDINO-G provided by an example of the present disclosure;

FIG. 4 shows the spectrogram of the Raman spectra of graphene dispersed by different dispersants (PSO, SDBS, PDINO and PDINO-G) provided by an example of the present disclosure;

FIG. 5 shows the spectrogram of the X-ray photoelectron spectroscopy (XPS) of PDINO and PDINO-G provided by an example of the present disclosure;

FIG. 6 is a schematic diagram showing the molecular structure and mechanism of some of the materials used in the organic solar cells in Examples 1-4 of the present disclosure;

FIG. 7 shows a J-V curve of an organic solar cell according to an example of the present disclosure;

FIG. 8 shows a J-V curve of the organic solar cell according to another example of the present disclosure;

FIG. 9 shows a J-V curve of the organic solar cell according to yet another example of the present disclosure; and

FIG. 10 is a schematic structural diagram of a reverse device (A) and a forward device (B) of an organic photoelectric device 100 according to an example of the present disclosure, wherein 101—anode; 102—anode interface layer; 103—active layer; 104—cathode interface modification layer; and 105—cathode.

### DETAILED DESCRIPTION OF EMBODIMENTS

In order to make the objects, technical solutions and advantages of the examples of the present disclosure clearer, the technical solutions of the examples of the present disclosure will be described clearly and completely below. Examples are carried out in accordance with conventional conditions or conditions recommended by the manufacturer if no specific conditions are specified in the examples. Reagents or instruments used, whose manufacturers are not specified, are all conventional products that are available commercially.

The present disclosure systematically discloses and establishes a high-efficient interface modification strategy, in which a carbon nanomaterial is added to a cathode interfacial material having dispersibility, and solves the problems of solution processability and work function of the carbon nanomaterial.

The present disclosure provides a cathode interface modification material composition, comprising:
a) an alcohol solvent;
b) an organic cathode interfacial material, wherein the organic cathode interfacial material is alcohol soluble, wherein the organic cathode interfacial material is dissolved in the above alcohol solvent to form a solution of organic cathode interfacial material; and
c) a carbon nanomaterial, wherein the carbon nanomaterial is uniformly dispersed in the solution of the above organic cathode interfacial material. In some embodiments, the carbon nanomaterial may have a maximum dimension of less than or equal to 5 μm.

The present disclosure further provides a method for preparing the above cathode interface modification material composition, comprising ultrasonically treating a solution mixture comprising a carbon nanomaterial, an organic cathode interface modification material and an alcohol solvent, to cause the carbon nanomaterial to be uniformly dispersed in the alcohol solvent to form a suspension.

In one or more embodiments, the method for preparing the above cathode interface modification material composition comprises: (a) dissolving a cathode interfacial material in an alcohol solvent at room temperature to form an alcohol solution of cathode interfacial material; (b) adding a carbon nanomaterial to the alcohol solution of cathode interfacial material to form an alcohol solution of cathode interfacial material containing the carbon nanomaterial; and (c) subjecting the alcohol solution of cathode interfacial material to ultrasonic treatment to obtain an alcohol solution of cathode interfacial material dispersed with the carbon nanomaterial.

In one or more embodiments, the ultrasonic treatment is performed at a low temperature; for example, the ultrasonic treatment is performed at a temperature of 0-15° C.; for example, at a temperature of 0-10° C., or even at a temperature of 0° C.-5° C.

In one or more embodiments, the low temperature may be realized by an ice bath.

The method for preparing the above cathode interface modification material composition provided by the present disclosure is easy to implement, increases the utilization rate of the carbon nanomaterial, and forms a dispersion liquid where the carbon nanomaterial is uniformly dispersed, which dispersion liquid exhibits obvious Tyndall effect under the condition of illumination.

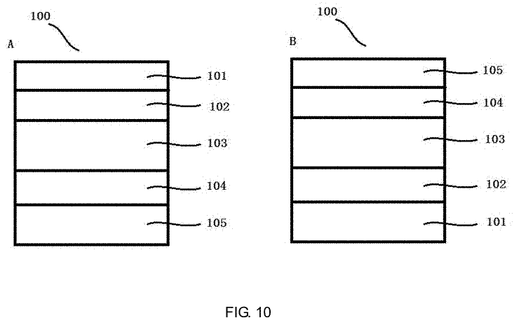

As shown in FIG. 10, the present disclosure further provides a cathode interface modification layer 104, comprising an organic cathode interfacial material and a carbon nanomaterial uniformly dispersed in the organic cathode interfacial material. In some embodiments, the carbon nanomaterial has a maximum dimension of less than or equal to 5 μm.

The cathode interface modification layer 104 provided by the present disclosure has excellent conductivity and charge mobility, and can maintain high energy conversion efficiency in photoelectric devices.

The present disclosure further provides a method for preparing the above cathode interface modification layer 104, comprising applying the above cathode interface modification material composition to a cathode 105 or an active layer 103.

The present disclosure further provides an organic photoelectric device 100, comprising the above cathode interface modification layer 104.

In one or more embodiments, the organic photoelectric device 100 is an organic solar cell, an organic light emitting diode, a perovskite solar cell, a photodetector or a super capacitor; for example, the organic photoelectric device is an organic solar cell.

The present disclosure further provides a method for fabricating the above organic photoelectric device 100, comprising applying the above cathode interface modification material composition to a cathode 105 or an active layer 103.

The present disclosure further provides use of the above cathode interfacial material composition in the fabrication of an organic photoelectric device 100.

A. Alcohol Solvent

In one or more embodiments, the alcohol solvent is selected from a group consisting of methanol, ethanol, propanol, isopropanol, n-butanol, isobutanol, tert-butanol, pentanol, isoamylol, hexanol, heptanol, octanol, nonanol, decanol and combinations thereof; for example, the alcohol solvent is selected from a group consisting of methanol, ethanol, propanol, isopropanol and combinations thereof; such as ethanol. In one or more embodiments, the alcohol solvent is a volatile alcohol.

B. Cathode Interfacial Material

In the present disclosure, the cathode interfacial material is an organic cathode interfacial material. In one or more embodiments, the organic cathode interfacial material is alcohol soluble (or can be dissolved in an alcohol). In one or more embodiments, the organic cathode interfacial material is soluble in methanol and/or ethanol, e.g., soluble in ethanol. For example, the cathode interfacial material may be an organic cathode interfacial material known in the art, such as a conventional organic cathode interfacial material.

In one or more embodiments, the organic cathode interfacial material contains a polar group or an ionic group. For example, the organic cathode interfacial material includes, but is not limited to, polar group or ionic group-containing conjugated small molecule organic cathode interfacial materials, conjugated polymer organic cathode interfacial materials, and organic non-conjugated material organic cathode interfacial materials. In one or more embodiments, the polar group or ionic group is selected from a group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group, an ester group, and combinations thereof.

In one or more embodiments, the organic cathode interfacial material is selected from conjugated small molecules, conjugated polymers, non-conjugated materials, or combinations thereof. For example, the organic cathode interfacial material is selected from the following (i), (ii), (iii), (iv) or combinations thereof:

(i) conjugated small molecules having the following formulas:

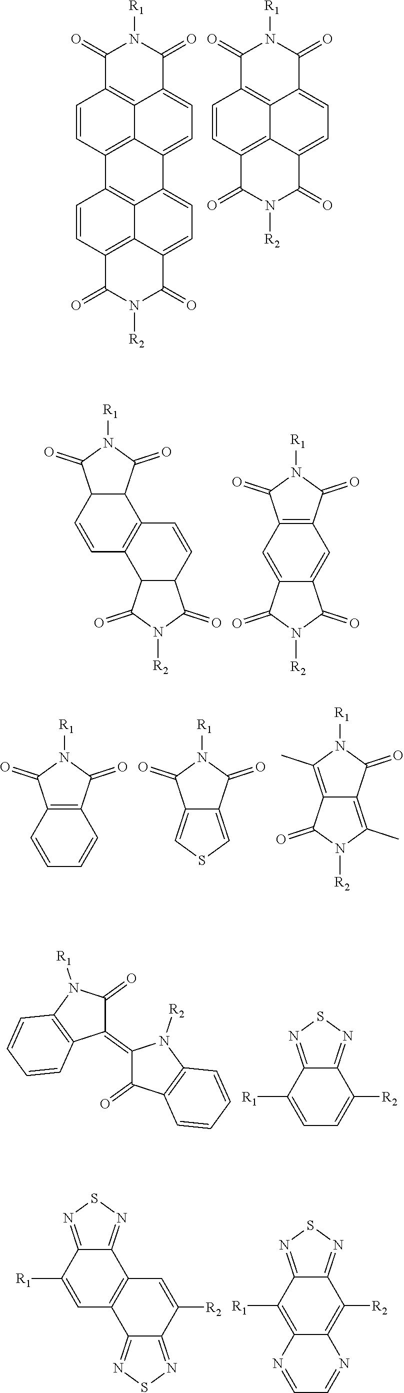

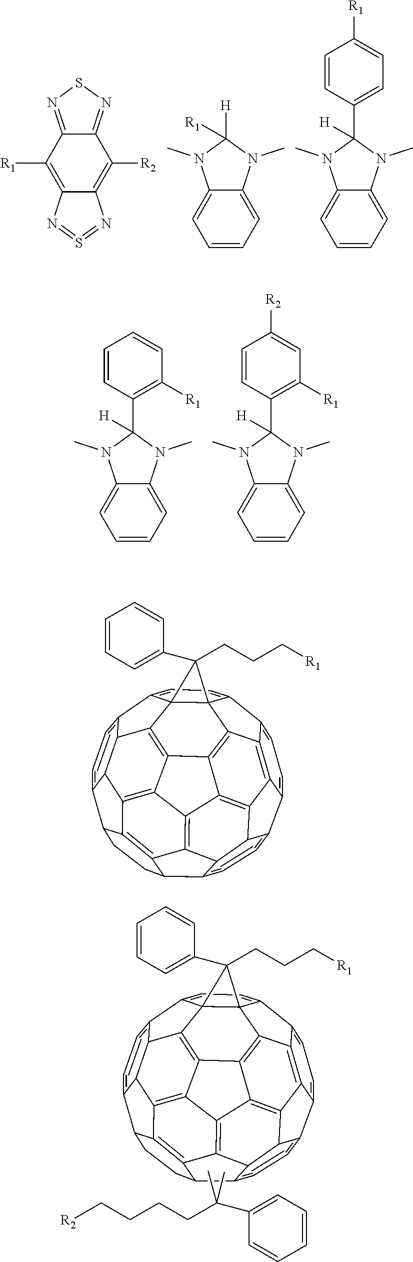

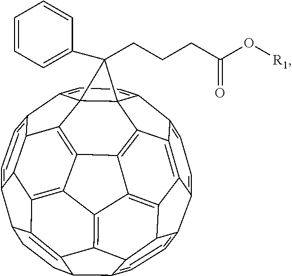

where R₁ and R₂ are each independently selected from a group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group;

(ii) A-D-A type conjugated small molecules having the following formula:

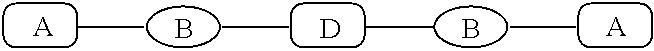

where A is a conjugated unit having an electron-withdrawing property, and is one or more selected from the group consisting of following structures:

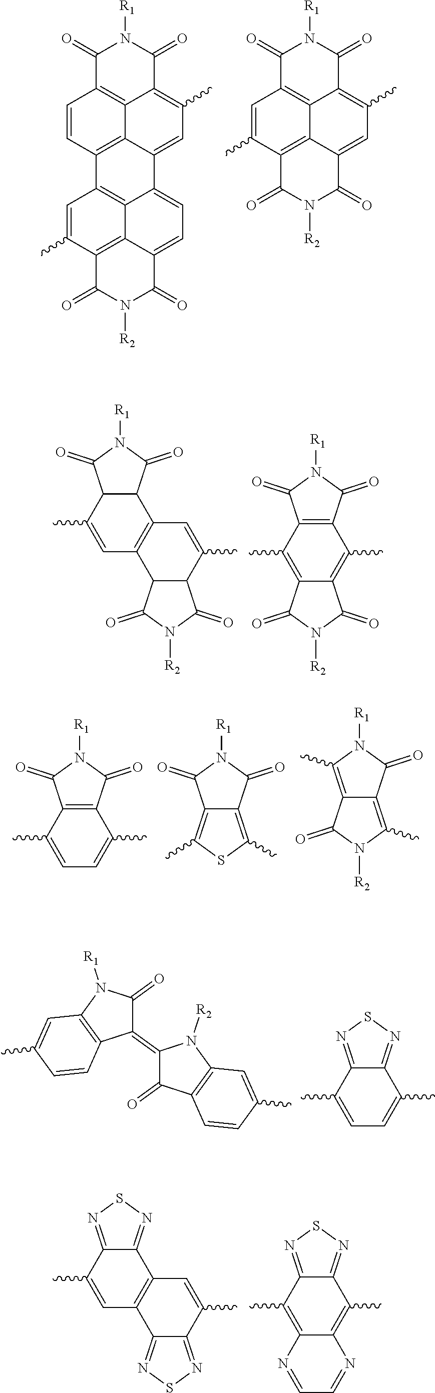

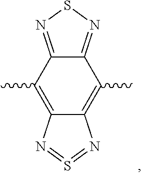

where R1 and R2 are independently selected from C₁₋₂₀ linear or branched alkyl groups, or C₃₋₂₀ cycloalkyl groups; and optionally, one or more of the carbon atoms in R₁ and R₂ is/are independently substituted by an oxo group, an alkenyl group, an alkynyl group, an aryl group, a hydroxy group, an amino group, a carbonyl group, a carboxyl group, an ester group, a cyano group, a nitro group, a fluorine atom, a chlorine atom, a bromine atom or an iodine atom;

B is a bridge bond connecting A and D conjugated units, and is one or more selected from the group consisting of following structures:

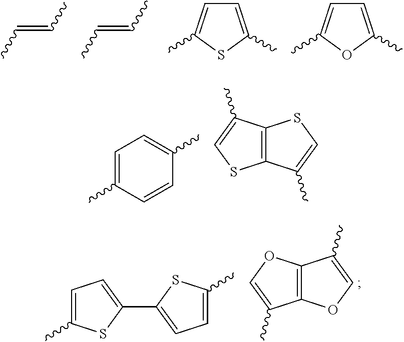

D is a conjugated unit having an electron-donating property, and is one or more selected from the group consisting of following structures:

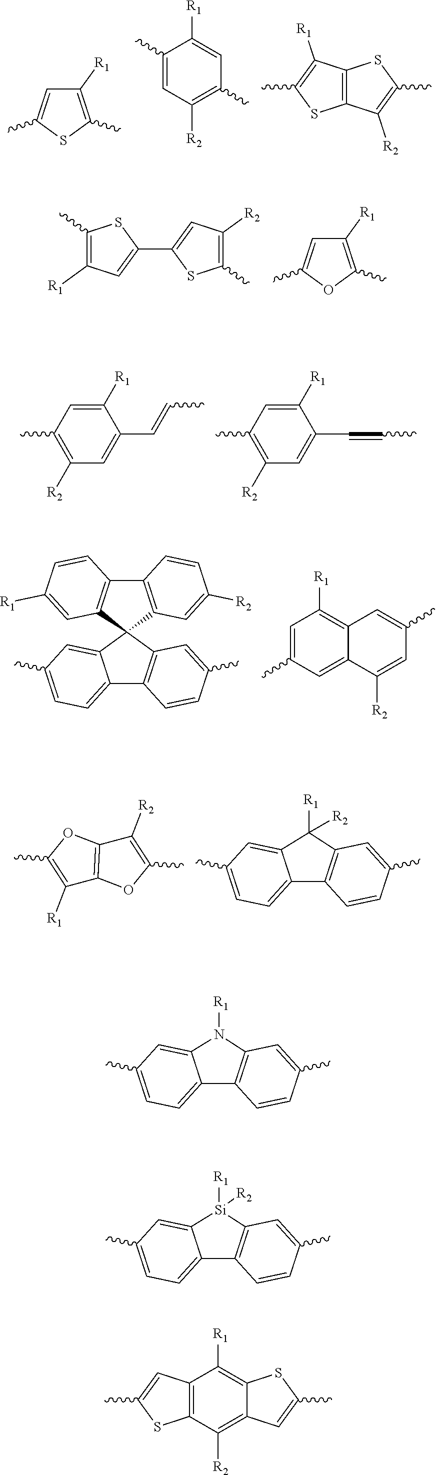

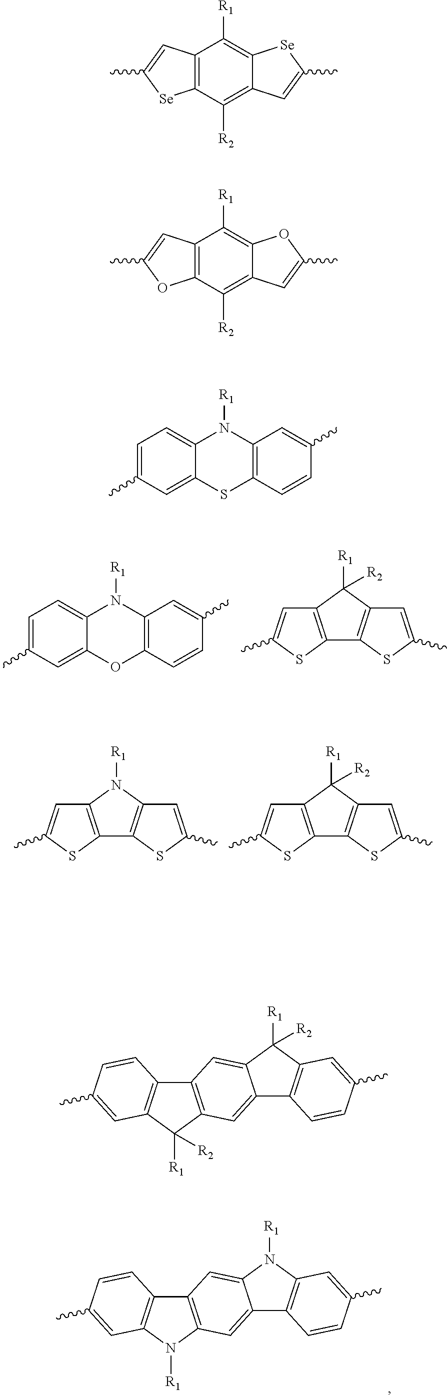

where R₁ and R₂ are independently selected from a group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group;

(iii) conjugated polymers having the following formula:

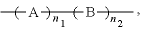

where n₁=1, 2, 3, 4 . . . , and n₂=0, 1, 2, 3 . . . ;

A and B are independently one or more selected from a group consisting of the following structures:

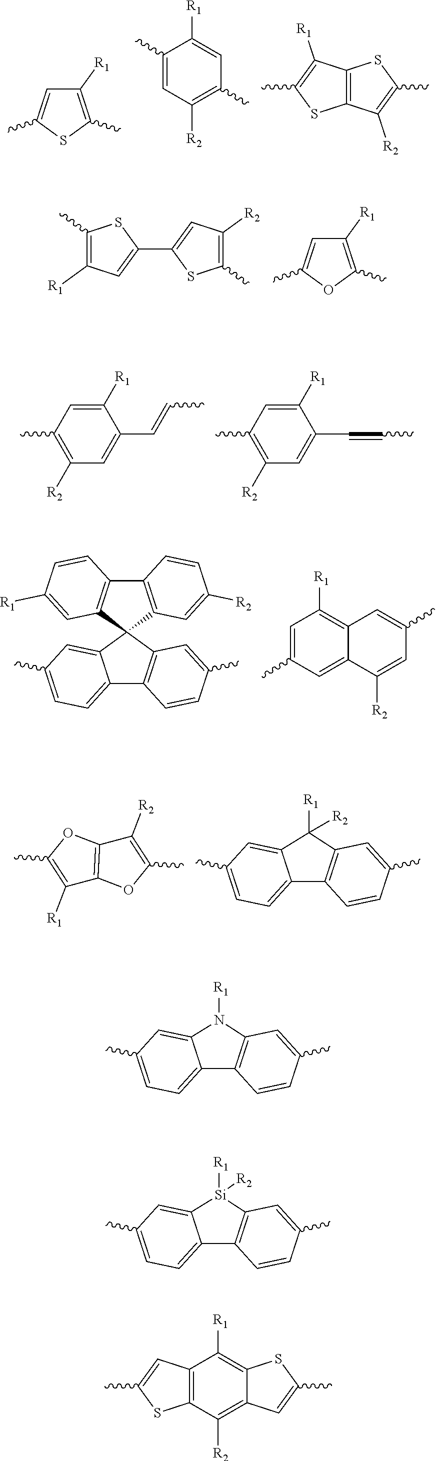

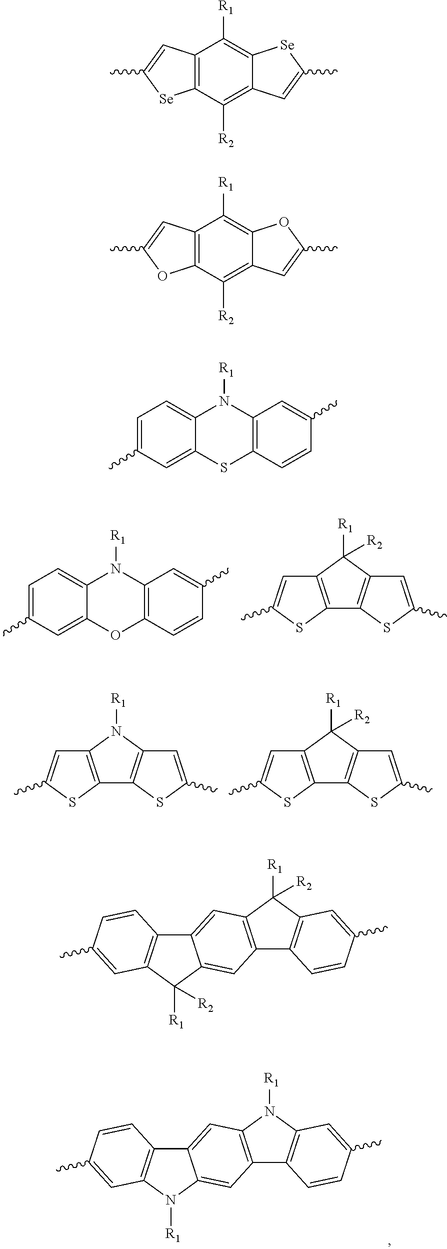

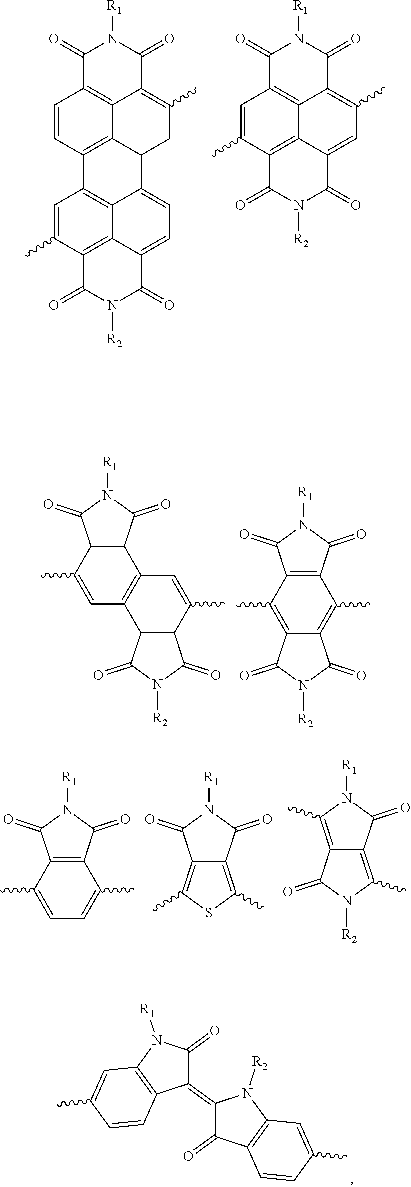

where R1 and R2 are independently selected from a group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group; and

(iv) non-conjugated materials having one of the following formulas:

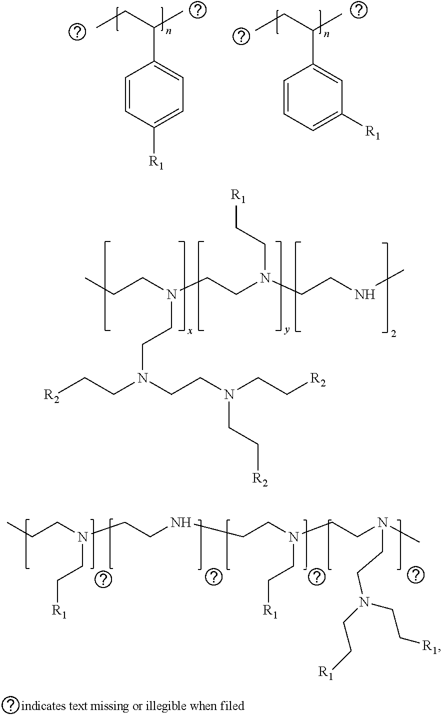

where R1 and R2 are independently selected from a group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group.

In one or more embodiments, the organic cathode interfacial material has one or more selected from the group consisting of following structures:

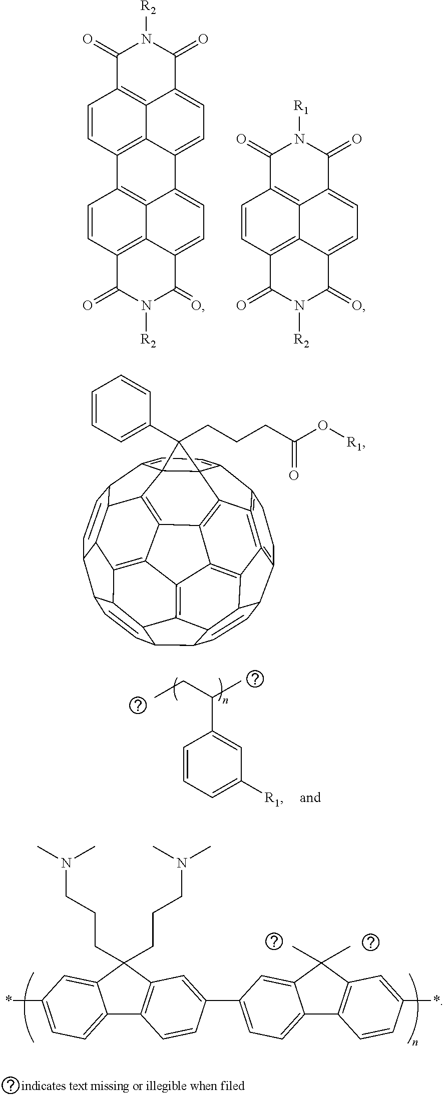

In one or more embodiments, the organic cathode interfacial material has the following structure:

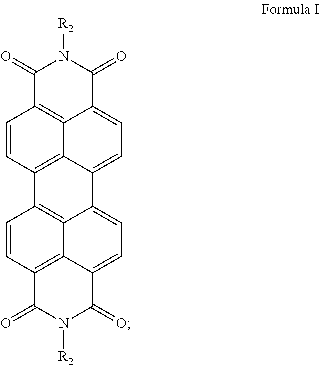

and in one or more embodiments, the organic cathode interfacial material is a perylene imide derivative. For example, the organic cathode interfacial material is perylene tetracarboxylic acid-bis(N,N-dimethylpropane-1-amine oxide)imide (PDINO).

In one or more embodiments, the organic cathode interfacial material has a negative surface adsorption energy for the carbon nanomaterial. For example, the organic cathode interfacial material has a surface adsorption energy of less than or equal to 3.510 for the carbon nanomaterial.

In one or more embodiments, the concentration of the organic cathode interfacial material in the cathode interface modification material composition (dispersion liquid) is 0.1-10 mg mL-1. In one or more embodiments, the concentration of the organic cathode interfacial material in the cathode interface modification material composition (dispersion liquid) is less than or equal to 10 mg mL-1, or less than or equal to 5 mg mL-1. In one or more embodiments, the concentration of the organic cathode interfacial material in the cathode interface modification material composition (dispersion liquid) is greater than or equal to 0.1 mg mL-1, or greater than or equal to 0.5 mg mL-1, or greater than or equal to 1 mg mL-1, or greater than or equal to 2 mg mL-1.

In one or more embodiments, the concentration of the compound of Formula I, such as PDINO, in the cathode interface modification material composition (dispersion liquid) is 0.1-10 mg mL-1. For example, the concentration of the compound of Formula I, such as PDINO, in the cathode interface modification material composition (dispersion liquid) is less than or equal to 10 mg mL-1, or less than or equal to 5 mg mL-1. For example, the concentration of the compound of Formula I, such as PDINO, in the cathode interface modification material composition (dispersion liquid) is greater than or equal to 0.1 mg mL-1, or greater than or equal to 0.5 mg mL-1, or greater than or equal to 1 mg mL-1, or greater than or equal to 2 mg mL-1.

C. Carbon Nanomaterial

In one or more embodiments, the carbon nanomaterial is selected from a group consisting of graphene quantum dots, single or multi-layer graphene, heteroatom-doped graphene, single-walled carbon nanotubes, few-walled carbon nanotubes, multi-walled carbon nanotubes, heteroatom-doped carbon nanotubes, and combinations thereof. For example, the carbon nanomaterial is single or multi-layer graphene.

According to some embodiments, the number of layers of graphene is 1-30. According to some embodiments, the number of layers of graphene sheets can be 1-10, for example, 1-5. According to some embodiments, graphene may be selected from one or more of single-layer graphene, double-layer graphene, and few-layer graphene having 3-10 layers.

According to some embodiments, the maximum dimension of the carbon nanomaterial is less than or equal to 5 μm. According to some embodiments, the average of the maximum dimension of the carbon nanomaterial is less than or equal to 5 μm, or less than or equal to 4 μm, or less than or equal to 3 μm, or less than or equal to 2 μm, or less than or equal to 1 μm, and at least one dimension is less than or equal to 200 nm, or less than or equal to 150 nm, or less than or equal to 100 nm, or less than or equal to 50 nm, or less than or equal to 30 nm, or less than or equal to 20 nm, or less than or equal to 10 nm, or less than or equal to 5 nm, or less than or equal to 3 nm, or less than or equal to 2 nm. The maximum dimension of the carbon nanomaterial refers to the maximum of the three-dimensional sizes of the carbon nanomaterial. For example, for graphene, the maximum dimension refers to the diameter of the graphene sheet. In some embodiments, the graphene sheet has an average diameter of less than or equal to 5 μm, or less than or equal to 4 pm, or less than or equal to 3 μm, or less than or equal to 2 μm, or less than or equal to 1 pm. In some embodiments, the graphene sheet has an average thickness of less than or equal to 30 nm, or less than or equal to 20 nm, or less than or equal to 10 nm, or less than or equal to 5 nm, or less than or equal to 3 nm, or less than or equal to 2 nm. In some embodiments, the graphene sheet has an average thickness of 0.6-30 nm, or 0.8-20 nm, 1-10 nm, or 1-5 nm, or 0.6-30 nm.

For a carbon nanotube, the maximum dimension is typically the length of the carbon nanotube. According to some embodiments, the average length of the carbon nanotubes is less than or equal to 5 μm, or less than or equal to 4 μm, or less than or equal to 3 μm, and the average diameter is less than or equal to 200 nm, or less than or equal to 150 nm, or less than or equal to 100 nm, or less than or equal to 50 nm, or less than or equal to 30 nm, or less than or equal to 20 nm, or less than or equal to 10 nm, or less than or equal to 5 nm, or less than or equal to 3 nm, or less than or equal to 2 nm.

In one or more embodiments, the weight ratio of the carbon nanomaterial to the cathode interfacial material in the cathode interface modification material composition (dispersion liquid) is less than or equal to 0.2, e.g., less than or equal to 0.15. The weight ratio of the carbon nanomaterial to the cathode interfacial material is from about 0.05 to about 0.2, or from about 0.08 to about 0.12, or from about 0.1 to about 0.15. For example, the graphene/PDINO weight ratio is less than or equal to 0.2, and higher PDINO concentrations and graphene proportions may cause graphene to agglomerate.

In the cathode interface modification material composition (dispersion liquid), the carbon nanomaterial is uniformly dispersed in a solution with little or no agglomeration. For example, the carbon nanomaterial is present in a solution in colloidal form. Typically, Tyndall phenomenon may be observed when the cathode interface modification material composition (dispersion liquid) is irradiated with light. The cathode interface modification material composition (dispersion liquid) may be stored for a long period of time without agglomeration or deposition. For example, the cathode interface modification material composition (dispersion liquid) may exist stably for at least 10 min, or at least 30 min, or at least 60 min, or at least 2 h, or at least 10 h, or at least 24 h, or at least 2 days, or at least 5 days, or at least 10 days, or at least 30 days.

D. Organic Photoelectric Device

As shown in FIG. 10, the present disclosure further provides an organic photoelectric device 100 comprising the above cathode interface modification layer described above. In one or more embodiments, the organic photoelectric device 100, such as an organic solar cell, further comprises a cathode 105, an active layer 103, an anode interface layer 102 and an anode 101.

As shown in FIG. 10, in one or more embodiments, the organic photoelectric device 100 comprises:

a cathode 105,

the above cathode interface modification layer 104, disposed on the cathode 105,

an anode 101, and

an active layer 103, disposed between the cathode interface modification layer 104 and the anode 102.

In one or more embodiments, the organic photoelectric device 100 further comprises an anode interface layer 102, disposed between the anode 101 and the active layer 103.

As shown in FIG. 10, in one or more embodiments, the organic photoelectric device 100 comprises:

a cathode 105,

the above cathode interface modification layer 104, disposed on the cathode 105,

an anode 101,

an anode interface layer 102, disposed on the anode 101, and

an active layer 103, disposed between the cathode interface modification layer 104 and the anode interface layer 102.

In one or more embodiments, the organic photoelectric device 100 comprises:

a cathode 105,

the above cathode interface modification layer 104,

an anode 101,

an anode interface layer 102, and

an active layer 103, disposed between the cathode interface modification layer 104 and the anode interface layer 102;

wherein the cathode interface modification layer 104 is disposed between the cathode 105 and the active layer 103; and the anode interface layer 102 is disposed between the anode 101 and the active layer 103.

The organic photoelectric device 100 may be a forward device or a reverse device. In one or more embodiments, the organic solar cell is a forward device, structurally comprising an anode 101, an anode interface layer 102, an active layer 103, a cathode interface modification layer 104 and a cathode 105 in this order. In one or more embodiments, the organic solar cell is a reverse device, structurally comprising a cathode 105, a cathode interface modification layer 104, an active layer 103, an anode interface layer 102 and an anode 101 in this order.

In one or more embodiments, the substrate is selected from indium tin oxide glass (ITO) or evaporated gold electrodes.

In one or more embodiments, the anode 101 is a metal electrode. For example, the metal is selected from a group consisting of aluminum, magnesium, silver, copper, and combinations thereof.

In one or more embodiments, the anode interface layer 102 comprises an anode interfacial material. In one or more embodiments, the anode interface layer 102 comprises an anode interfacial material dispersed with graphene oxide.

In one or more embodiments, the active layer 103 comprises donor and acceptor materials. In one or more embodiments, the donor material is selected from a group consisting of PTQ10, PM6, and combinations thereof. In one or more embodiments, the acceptor material is selected from a group consisting of IDIC-2F, Y6, IDIC, MO-IDIC-2F, and combinations thereof. In one or more embodiments, the donor and acceptor material pair is selected from a group consisting of PTQ10:IDIC-2F, PM6:Y6, PTQ10:IDIC and PTQ10:MO-IDIC-2F.

In one or more embodiments, the cathode interface modification layer 104 comprises the above-described cathode interfacial material. In one or more embodiments, the cathode interface modification layer 104 comprises a cathode interfacial material dispersed with a carbon nanomaterial. In one or more embodiments, the cathode interface modification layer 104 comprises PDINO or NDINO dispersed with graphene.

In one or more embodiments, the cathode 105 is a metal electrode. For example, the metal is selected from a group consisting of aluminum, magnesium, silver, and copper.

The present disclosure further provides a method for fabricating the above-described organic photoelectric device 100, comprising applying the above-described cathode interface modification material composition, such that the resultant cathode interface modification layer 104 is sandwiched between the cathode 105 and the active layer 103. The present disclosure further provides a method for fabricating the above-described organic photoelectric device 100, comprising applying the above-described cathode interface modification material composition to the cathode 105 or the active layer 103.

In one or more embodiments, the method for fabricating the organic photoelectric device 100 comprises: A) providing an anode 101; B) forming an anode interface layer 102; C) applying an active material to form an active layer 103; D) applying the above-described cathode interface modification material composition to form a cathode interface modification layer 104; and E) forming a cathode 105. These steps may be performed in a different order.

In one or more embodiments, the method for fabricating the organic photoelectric device 100 comprises: A) providing an anode 101; B) forming an anode interface layer 102 on the anode 101; C) applying an active material to the anode interface layer 102 to form an active layer 103; D) applying the above cathode interface modification material composition to the active layer 103 to form a cathode interface modification layer 104; and E) forming a cathode 105 on the cathode interface modification layer 104.

In one or more embodiments, the method for fabricating the organic photoelectric device 100 comprises: A) providing a cathode 105; B) applying the above cathode interface modification material composition to the cathode 105 to form a cathode interface modification layer 104; C) applying an active material to the cathode interface modification layer 104 to form an active layer 103; D) forming an anode interface layer 102; and E) providing an anode 101.

In one or more embodiments, the active material comprises donor and acceptor materials. In one or more embodiments, the method for fabricating the organic photoelectric device 100 further comprises the above-described steps of preparing a cathode interface modification material composition.

In one or more embodiments, the method for fabricating a photovoltaic device comprises:

(1) cleaning a substrate and blow-drying the substrate, and placing the substrate into a UV-ozone processor for treatment;

(2) applying an anode interface layer 102 to the substrate;

(3) forming a blend of the donor material and the acceptor material and applying the blend to the anode interface layer 102; and

(4) evaporating a metal as a cathode 105.

In one or more embodiments, the above-mentioned application refers to the means of spin coating, brush coating, spray coating, dip coating, roller coating, screen printing, printing, inkjet printing or in situ polymerization. For example, the cathode interface modification layer 104 may be formed on the cathode 105 or the active layer 103 by means of spin coating.

In one or more embodiments, when the metal silver is used as the anode 101, the photovoltaic device may further comprise an anode hole buffer layer; for example, the anode hole buffer layer is MoO₃.

In one or more embodiments, the cathode interface modification layer 104 is formed to have a thickness of 5-32 nm, e.g., 5-18 nm, or 5-10 nm. In one or more embodiments, the cathode interface modification layer 104 is formed to have a thickness of 5 nm.

### EXAMPLES

Description of relevant materials:

Graphene (G) and graphene oxide (GO) were both purchased from Suzhou Hengqiu Graphene Technology Co., Ltd., without further purification.

PM6, Y6, IDIC, PDINO and NDINO were all purchased from Solarmer Materials, without further purification.

Poly(3,4-ethylenedioxythiophene):polystyrene sulfonate (PEDOT:PSS, PVP Al 4083) was synthesized by H. C. Starck.

The ITO substrate (15Ω per square) was purchased from Nippon Sheet Glass, PTQ10 (GPC:Mn=30.1 kDa; Mw/Mn=1.57 Anal.), IDIC-2F, Mo-IDIC-2F and PSO (GPC:Mn=15.6 kDa; Mw/Mn=1.60 Anal.) were synthesized according to the literatures.

### Example 1

A) Cathode Interface Modification Material Comprising Single or Multi-Layer Graphene and PDINO

The cathode interface modification material PDINO was dissolved in ethanol at room temperature at a concentration of 10.0 mg mL⁻¹, 20% graphene (purchased from Suzhou Hengqiu Graphene Technology Co., Ltd.) was added thereto, and the mixture was then subjected to ultrasonic treatment in a 0° C. ice bath for 30 min, thereby obtaining a PDINO-G alcohol phase dispersion liquid (2 mg mL⁻¹ PDINO containing 5% graphene).

As can be known from FIG. 2A, no obvious agglomeration was formed in the resultant PDINO-G dispersion liquid after standing for 10 min.

As can be known from FIG. 2B, the obtained dispersion liquid was irradiated with light, and exhibited obvious Tyndall effect.

Without theoretical limitation, the reasons why PDINO is selected as an organic cathode interfacial material for dispersing graphene are as follows: 1) PDINO is soluble in alcohol; 2) PDINO has a large planar electron defect π-system and ion moiety, and therefore can interact with graphene through π-π interaction, hydrophobic force and Coulomb attraction so as to disperse graphene, that is, PDINO has dispersibility for graphene and can be used as a dispersant for graphene; and 3) PDINO can adjust the work function of graphene as a cathode interfacial material.

Referring to Table 1, the adsorption energy of three different materials (including PDINO, sodium 1-pyrene sulfonate (PSA) and sodium dodecylbenzene sulfonate (SDBS)) on the surface of single-layer graphene was calculated according to the periodic density functional theory. PSA and SDBS are two common dispersants for dispersing graphene and exfoliating graphite into graphene. The three materials all have negative surface adsorption energy for graphene, that is, they all have certain dispersibility for graphene.

TABLE 1
Adsorption energy of three different organic interfacial materials on single-layer
graphene surface

| Chemical structure | Grapheme surface adsorption enemy (eV) |
|---|---|
| 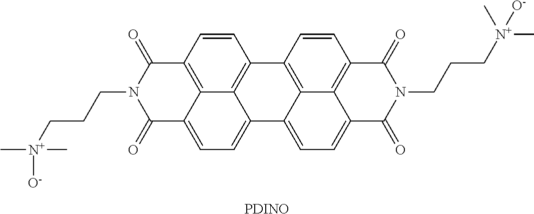 | −3.510 |
| 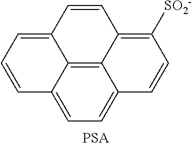 | −0.438 |
| 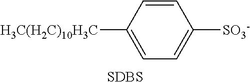 | −0.271 |

The experiment showed that when the concentration of PDINO was higher than 10.0 mg mL⁻¹, or when the graphene/PDINO weight ratio was higher than 20%, agglomeration occurred in graphene.

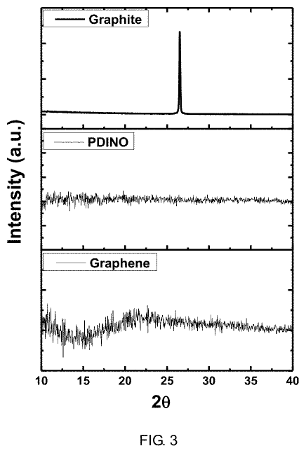

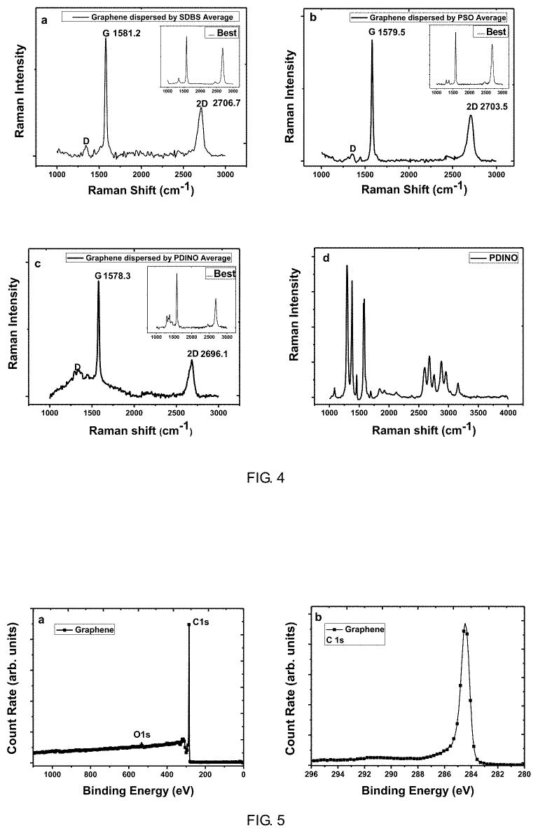

The dispersion characteristic of graphene was characterized by X-ray diffraction (XRD), Raman spectrum and X-ray photoelectron spectroscopy (XPS). As shown in FIG. 3, the XRD results showed that graphite had a sharp diffraction peak at 26.4°, PDINO dispersed graphene PDINO-G (2 mg mL⁻¹ PDINO containing 5% graphene) had a broad weak peak at the position of 22.5°, while pure PDINO did not have any diffraction peak in the range of 10−40°, which indicated that graphene in the resultant dispersion liquid was close to single-layer graphene. FIG. 4 is Raman spectra of graphene dispersed using different dispersants (PSO, SDBS, PDINO and PDINO-G). In the Raman spectrum of graphene dispersed in PDINO, the excitation wavelength was 532 nm, peak D caused by edge/defect in the graphene lattice occurred at the position of 1344 cm⁻¹, and peak G caused by sp² hybridized C═C double bond in the graphene lattice occurred at the position of 1578.3 cm⁻¹. Peak 2D occurred at the position of about 2700 cm⁻¹, and the intensity ratio of peak 2D to peak G indicated the presence of few-layer graphene. However, in the Raman spectrum of graphene dispersed in SDBS, peak G caused by sp² hybridized C═C double bond in the graphene lattice occurred at the position of 1581.2 cm⁻¹, and peak 2D occurred at the position of about 2700 cm⁻¹. In contrast, for graphene dispersed in PDINO, it was found that peak G had a red shift of ˜2.9 cm⁻¹ and peak 2D had a red shift of ˜10.6 cm⁻¹. Similar red shifts (peak G had a red shift of ˜1.7 cm⁻¹ and peak 2D had a red shift of ˜3.2 cm⁻¹) were also found for graphene dispersed in PSO. The red shifts demonstrate that graphene dispersed in PDINO is n-doped. FIG. 5 is an spectrogram of the X-ray photoelectron spectroscopy (XPS) of graphene powder, in which the peak of the binding energy of the sp² hybridized C═C double bond in the graphene lattice occurs at the position of 284.5 eV, and occupies a dominant position; and the peak of the relatively weak binding energy of the sp³ hybridized C—C single bond occurs at the position of 285.3 eV, which demonstrates that the defect content of graphene sheet is relatively low.

According to the atomic force microscope (AFM), it was calculated that the graphene had a sheet diameter of less than or equal to 5 μm, and an average thickness of about 1.861 nm, which was few-layer graphene (less than two layers).

In order to find out the mechanism by which the PDINO-G cathode interface modification material improves the photovoltaic efficiency of organic solar cells, the work function of the cathode interfacial material on various substrates was measured using Scanning Kelvin probe microscopy and Ultraviolet Photoelectron Spectroscopy (UPS). Table 2 shows the work functions of PDINO-G in which graphene is doped into ITO or evaporated gold electrodes at different proportions. The results of UPS showed that after the deposition of the PDINO layer, the work function of the ITO electrode decreased from 4.43 eV to 3.64 eV, and the work function of the evaporated gold electrode decreased from 4.44 eV to 3.77 eV. The deposition of the PDINO-G layer decreased the work function of the ITO electrode to 3.82-4.09 eV, and decreased the work function of the evaporated gold electrode to 3.83-4.01 eV, depending on the proportion of graphene doped in the PDINO-G. The SKPM measurement results had the same trend as the UPS results.

TABLE 2
Work functions of PDINO-G with different proportions
of graphene measured on different substrates

| | | Top layer | | | | | |
|---|---|---|---|---|---|---|---|
| | | | | 1% G/ | 5% G/ | 10% G/ | 20% G/ |
| Measuring | | None | PDIMQ | PDINO | PDINO | PDINO | PDINO |
| method | Substrate | [eV] | [eV] | [eV] | [eV] | [eV] | [eV] |
| SKPM | Au(evaporation) | 4.65 | 3.80 | 4.02 | 4.12 | 4.16 | 4.2S |
| | ITO | 4.70 | 3.96 | 4.15 | 4.18 | 4.30 | 4.43 |
| UPS | Au(evaporation) | 4.44 | 3.77 | 3.83 | 3.92 | 3.98 | 4.01 |
| | ITO | 4.43 | 3.64 | 3.82 | 3.86 | 3.91 | 4.09 |

### B) Preparation of Organic Solar Cells

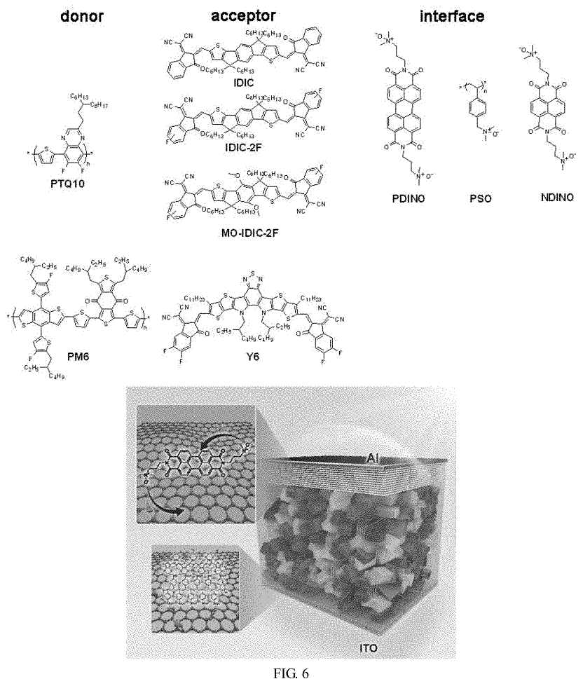

An organic solar cell was constructed by using graphene dispersed in PDINO (hereinafter referred to as PDINO-G) as a cathode interfacial material. The anode interfacial material was graphene oxide doped PEDOT:PSS (hereinafter referred to as PEDOT:PSS-GO). A classical active layer system was selected, which was composed of the donor material of poly(thieno-6,7-difluoro-2-(2-hexyldecyloxy)quinoxaline) (PTQ10) and the acceptor material of 2,2′-[[4,4,9,9-tetrahexyl-4,9-dihydro-s-indacene[1,2-b:5,6-b′]dithiophene-2,7-diyl]bis[ylidenylmethyl-5 or 6-fluoro-(3-oxo-1H-indene-2,1(3H)-dimethylene)]]dimalononitrile (IDIC-2F). A photovoltaic device having the structure of ITO/PEDOT:PSS-GO/PTQ10:IDIC-2F/PDINO-G/Al (100 nm) was fabricated. In this example, the molecular structure of the material used for the organic solar cell and the mechanism of the device are as shown in FIG. 6.

For a forward device, an ITO substrate (Lumtec, 5Ω sq⁻¹) was sequentially washed ultrasonically three times with a 5% detergent, 5-10 min each time; washed ultrasonically three times with deionized water, 5-10 min each time; washed three times with acetone, 5-10 min each time; and washed ultrasonically three times with isopropyl alcohol, 5-10 min each time. The resultant ITO substrate was blow-dried with a nitrogen gun, put into a UV-ozone (Novascan PDS-UVT) processor for ozone treatment for 10 min at 30° C., then spin-coated with about 30 nm of PEDOT:PSS or PEDOT:PSS-GO (at a rotational speed of 4200 rpm for 30 s), and then subjected to a thermal annealing treatment at 150° C. in air, wherein the PEDOT:PSS-GO dispersion liquid contains 0.5% graphene oxide. The substrate was then transferred to a nitrogen protective glove box. The donor and acceptor-blended active layer solution was dissolved in chloroform at a concentration of about 15 mg/ml, which was stirred in a glove box at 40° C. for about 2 h. The blending ratio of the active layer was PTQ10:IDIC-2F (1:1 wt.). Thereafter, spin coating of the active layer 103 was performed in the glove box, with the film thickness of the active layer 103 being about 100 nm. The active layer 103 after spin coating was subjected to a thermal annealing treatment at 100-120° C. for 5 min. An ethanol dispersion liquid of PDINO-G (containing 5% graphene) cathode interface modification layer material at a concentration of 2.0 mg mL⁻¹ was then spin-coated on the treated active layer 103 at a rotational speed of 3000 rpm. The apparatus for evaporation was purchased from Technol. Generally, 100-120 nm of metal aluminum is evaporated under vacuum condition (2×10⁻⁶ Pa) as the cathode 105 of the photovoltaic device, with the evaporation speed being 1-3 Å/s.

C) Analysis of Photovoltaic Property

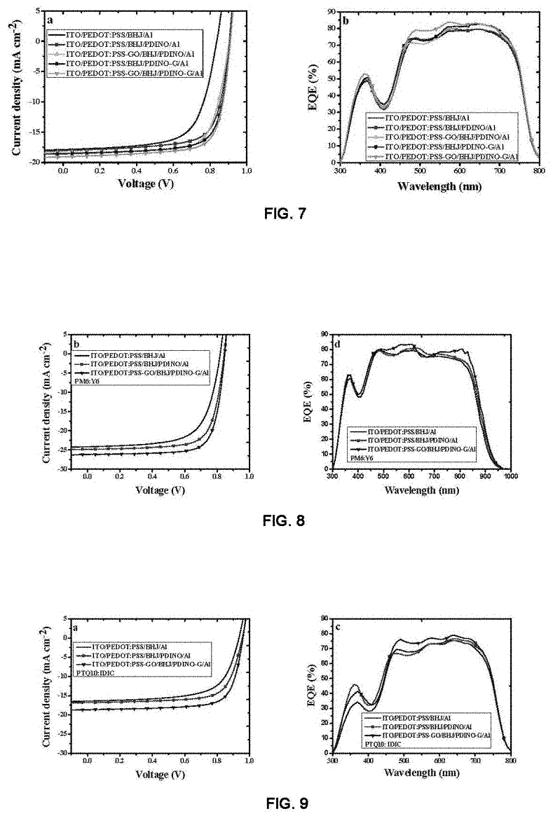

FIG. 7 shows a J-V curve of an organic solar cell of this example. The spectra of external quantum efficiency (EQE) of all the devices are as shown in FIG. 7. Table 3 lists the photovoltaic parameters of the devices having different structures. The photovoltaic devices that do not use any cathode interface modification material have a relatively low photoelectric conversion efficiency (PCE), which is only 10.15% (open-circuit voltage (V_{OC})=0.84 V, short-circuit current (J_{SC})=17.89 mA cm⁻², and fill factor (FF)=67.55%). When a classical cathode interface modification material PDINO is inserted, the PCE is 11.81% (open-circuit voltage=0.90 V, short-circuit current=18.06 mA cm⁻², and fill factor=72.66%). When PDINO dispersed graphene PDINO-G is used as the cathode interface modification layer 104, the PCE of the device is increased to 12.58% (open-circuit voltage=0.91 V, short-circuit current=18.57 mA cm⁻², and fill factor=74.43%). When PEDOT:PSS-GO is used instead of PEDOT:PSS as the anode interface layer 102 and PDINO is still used as the cathode interface modification layer 104, the PCE of the device is 12.23% (open-circuit voltage=0.90 V, short-circuit current=18.39 mA cm⁻², and fill factor=73.92%). When the graphene modified cathode interface modification layer PDINO-G and the anode interface layer 102 PEDOT:PSS-GO are used simultaneously, the PCE of the device is significantly increased to 13.01% (open-circuit voltage=0.91 V, short-circuit current=19.09 mA cm⁻², and fill factor=74.87%). The integral current density value (J_{calc}) calculated by EQE spectrum is in good agreement with the short-circuit current value calculated by the J-V curve.

TABLE 3
Photovoltaic property data (AM 1.5 G, 100 mW cm⁻²) of organic
solar cells (OSC) having different interface modification layers
prepared according to Example 1 of the present disclosure

| | V [symbol] | J [symbol] (J [symbol] ) | FF | PCEₘₐₓ | PCE_{avg} |
|---|---|---|---|---|---|
| Structure of OSC | [V] | [mA cm⁻²] | [%] | [%] | [%] |
| ITOPEDOT:PSS/BHI/ | 0.84 | 17.89(17.37) | 67.55 | 10.15 | 9.9 ± 0.3 |
| Al | | | | | |
| ITO/PEDOT:PSS/ | 0.90 | 18.06(17.53) | 72.66 | 11.81 | 11.5 ± 0.3 |
| BHJ/PDINO/Al | | | | | |
| ITO/PDOT:PSS-GO/ | 0.90 | 18.39(17.84) | 73.92 | 12.23 | 11.9 ± 0.3 |
| BHJ/PDINO/Al | | | | | |
| ITO/PEDOT:PSS/ | 0.91 | 18.57(18.01) | 74.43 | 12.58 | 12.4 ± 0.2 |
| BHJ/PDINO-G/Al | | | | | |
| ITO/PEDOT:PSS-GO/ | 0.91 | 19.09(18.31) | 74.87 | 13.01 | 12.8 ± 0.2 |
| BHJ/PDINO-G/Al | | | | | |

[symbol]

J [symbol] comes from EQE spectrum; and for brevity, BHJ is used instead of active layer. [symbol]
indicates data missing or illegible when filed

D) Influence of Different Doping Proportions on Photovoltaic Devices

The influence of different graphene doping proportions in the PDINO-G cathode interface modification material on the photovoltaic property of the photovoltaic devices was systematically studied, as shown in Table 4.

TABLE 4
Influence of different graphene doping proportions
on photovoltaic property of photovoltaic devices

| Proportion | V [symbol] | J [symbol] | FF | PCE |
|---|---|---|---|---|
| of graphene | [V] | [mA cm⁻²] | [%] | [%] |
| 1% | 0.90 | 17.82 | 71.66 | 11.49 |
| 2% | 0.90 | 18.13 | 71.76 | 11.71 |
| 3% | 0.90 | 18.43 | 72.25 | 11.98 |
| 4% | 0.90 | 18.53 | 72.07 | 12.02 |
| 5% | 0.91 | 18.36 | 72.88 | 12.18 |
| 6% | 0.91 | 18.54 | 73.52 | 12.40 |
| 7% | 0.91 | 18.46 | 73.07 | 12.27 |
| 8% | 0.90 | 18.45 | 72.60 | 12.06 |
| 9% | 0.90 | 18.12 | 72.60 | 11.84 |
| 10% | 0.90 | 17.90 | 72.43 | 11.67 |
| 20% | 0.90 | 17.92 | 71.60 | 11.51 |

[symbol]

indicates data missing or illegible when filed

E) Analysis of Thickness Sensitivity

The regulation of thickness of the cathode interface modification material is of great significance for large area preparation of organic solar cells. Therefore, the influence of the thickness of the interfacial material on the photovoltaic property of the device was studied. Table 5 lists photovoltaic property parameters based on PEQ10:IDIC-2F devices for different PDINO-G thicknesses. Even if the thickness of the PDINO-G is 30 nm, the PCE of the device remains to be 12% or higher, and this is due to the relatively high charge mobility/conductivity and good electronic properties of the PDINO-G, and energy levels that match the active layer of the organic solar cell.

TABLE 5
Influence of different PDINO-G thicknesses on the property
of photovoltaic devices under optimized conditions

| Thickness of | V [symbol] | J [symbol] | FF | PCEₘₐₓ | PCE [symbol] |
|---|---|---|---|---|---|
| PDINO-G | [V] | [mA cm⁻²] | [%] | [%] | [%] |
| 5 nm | 0.91 | 19.09 | 74.87 | 13.01 | 12.8 ± 0.2 |
| 10 nm | 0.91 | 18.89 | 74.66 | 12.84 | 12.5 ± 0.3 |
| 18 nm | 0.91 | 18.83 | 74.18 | 12.71 | 12.4 ± 0.3 |
| 32 nm | 0.91 | 18.76 | 73.72 | 12.60 | 12.4 ± 0.2 |

[symbol]

indicates data missing or illegible when filed

F) Measurement of Device Roughness

Roughness (RMS) was measured using an atomic force microscope, and the results were listed in Table 6.

TABLE 6
Roughness of different OSC structures

| Active layer | Structure of OSC | RMS (nm) |
|---|---|---|
| PTQ10:IDIC-2F | ITO/PEDOT:PSS/BHJ | 0.96 |
| | ITO/PEDOT:PSS-GO/BHJ | 0.98 |
| | ITO/PEDOT:PSS/BHJ/PDINO | 0.91 |
| | ITO/PEDOT:PSS/BHJ/PDINO-G | 1.49 |

[symbol]

For brevity, BHJ is used instead of active layer. [symbol]
indicates data missing or illegible when filed

G) Testing of the Universality of the Devices

In order to verify the universality of PDINO-G in organic solar cell devices, the photovoltaic property parameters of the devices were measured by using PTQ10:IDIC-2F as the active layer 103 and using different cathode materials, and comparison was made. The results were as shown in Table 7.

TABLE 7
Photovoltaic property of different OSC structures

| | V_{OC} | J_{SC}(Jcalc. [symbol] ) | FF | | PCE [symbol] |
|---|---|---|---|---|---|
| Structure of OSC | [V] | [mA cm⁻²] | [%] | PCEₘₐₓ | [%] |
| ITO/PEDOT:PSS/ | 0.84 | 17.89(17.37) | 67.55 | 10.15 | 9.9 ± 0.3 |
| BHJ/Al | | | | | |
| ITO/PEDOT:PSS/ | 0.90 | 18.06(17.53) | 72.66 | 11.81 | 11.5 ± 0.3 |
| BHJ/PDINO/Al | | | | | |
| ITO/PEDOT:PSS-GO/ | 0.91 | 19.09(18.31) | 74.87 | 13.01 | 12.8 ± 0.2 |
| BHJ/PDINO-G/Al | | | | | |
| ITO/PEDOT:PSS-GO/ | 0.90 | 18.91(18.34) | 68.53 | 11.66 | 11.4 ± 0.3 |
| BHJ/PDINO-G/Ag | | | | | |
| ITO/PEDOT:PSS-GO/ | 0.89 | 17.01(16.50) | 69.31 | 10.49 | 10.2 ± 0.3 |
| BHJ/PDINO-G/Au | | | | | |

[symbol]

J_{calc} comes from EQE spectrum; and for brevity, BHJ is used instead of active layer. [symbol]
indicates data missing or illegible when filed

### Example 2

A. A cathode interfacial material modification composition comprising graphene and PDINO was prepared using the same method as that used in Example 1.
B. An organic solar cell was prepared using a method similar to that of Example 1, in which PM6 was used instead of PTQ10 as the donor material and Y6 was used instead of IDIC-2F as the acceptor material, wherein PM6:Y6 was 1:1.2 wt, and 0.5% chloronaphthalene was added.
C. Analysis of photovoltaic property

FIG. 8 shows a J-V curve of an organic solar cell of this example. The spectra of external quantum efficiency (EQE) of all the devices are as shown in FIG. 8. Table 8 lists the photovoltaic parameters of the devices having different structures. The photovoltaic devices that do not use any cathode interface modification material have a relatively low photoelectric conversion efficiency (PCE), which is only 12.9% (open-circuit voltage (VOC)=0.82 V, short-circuit current (JSC)=24.15 mA cm-2, and fill factor (FF)=66.95%). When a classical cathode interface modification material PDINO is inserted, the PCE is 15.1% (open-circuit voltage=0.84 V, short-circuit current=24.84 mA cm-2, and fill factor=73.43%). When PDINO dispersed graphene PDINO-G is used as the cathode interface modification layer 104, the PCE of the device is increased to 16.3% (open-circuit voltage=0.85 V, short-circuit current=25.65 mA cm-2, and fill factor=75.78%).

TABLE 8
Photovoltaic property data (AM 1.5 G, 100 mW
cm⁻²) of organic solar cells (OSC) prepared
according to Example 2 of the present disclosure

| | V [symbol] | J [symbol] (J [symbol] ) | FF | PCEₘₐₓ | PCE_{avg} |
|---|---|---|---|---|---|
| Structure of OSC | [V] | [mA cm⁻²] | [%] | [%] | [%] |
| ITO/PEDOT:PSS/ | 0.82 | 24.15(23.67) | 66.95 | 13.26 | 12.9 ± 0.3 |
| BHJ/Al | | | | | |
| ITO/PEDOT:PSS/ | 0.84 | 24.84(24.34) | 73.43 | 15.32 | 15.1 ± 0.2 |
| BHJ/PDIN/Al | | | | | |
| ITO/PEDOT:PSS-GO/ | 0.85 | 25.65(25.14) | 75.78 | 16.52 | 16.3 ± 0.2 |
| BHJ/PDINO-G/Al | | | | | |
| ITO/PEDOT:PSS-GO/ | 0.84 | 25.68(25.17) | 68.81 | 14.84 | 14.5 ± 0.3 |
| BHJ/PDINO-G/Ag | | | | | |
| ITO/PEDOT:PSS-GO/ | 0.83 | 24.05(23.57) | 68.86 | 13.75 | 13.4 ± 0.3 |
| BHJ/PDINO-G/Au | | | | | |

[symbol]

J [symbol] comes from EQE spectrum; and for brevity, BHJ is used instead of active layer. [symbol]
indicates data missing or illegible when filed

D. Measurement of device roughness

Roughness (RMS) was measured using an atomic force microscope, and the results were listed in Table 9.

TABLE 9
Roughness (RMS) of different OSC structures

| Active layer | Structure of OSC | RMS (nm) |
|---|---|---|
| PM6:Y6 | ITO/PEDOT:PSS/BHJ | 1.28 |
| | ITO/PEDOT:PSS-GO/BHJ | 1.33 |
| | ITO/PEDOT:PSS/BHJ/PDINO | 1.24 |
| | ITO/PEDOT:PSS/BHJ/PDINO-G | 1.35 |

[symbol]

For brevity, BHJ is used instead of active layer. [symbol]
indicates data missing or illegible when filed

### Example 3

A. A cathode interfacial material modification composition comprising graphene and PDINO was prepared using the same method as that used in Example 1.
B. An organic solar cell was prepared using a method similar to that of Example 1, in which IDIC was used instead of IDIC-2F as the acceptor material, wherein PTQ10:IDIC was 1:1 wt.
C. Analysis of photovoltaic property

FIG. 9 shows a J-V curve of an organic solar cell of this example. The spectra of external quantum efficiency (EQE) of all the devices are as shown in FIG. 9. Table 10 lists the photovoltaic parameters of the devices having different structures. The photovoltaic devices that do not use any cathode interface modification material have a relatively low photoelectric conversion efficiency (PCE), which is only 9.8% (open-circuit voltage (V_{OC})=0.93 V, short-circuit current (J_{SC})=16.44 mA cm⁻², and fill factor (FF)=66.06%). When a classical cathode interface modification material PDINO is inserted, the PCE is 11.3% (open-circuit voltage=0.96 V, short-circuit current=16.80 mA cm⁻², and fill factor=72.02%). When PDINO dispersed graphene PDINO-G is used as the cathode interface modification layer 104, the PCE of the device is increased to 12.2% (open-circuit voltage=0.96 V, short-circuit current=17.43 mA cm⁻², and fill factor=74.34%).

TABLE 10
Photovoltaic property data (AM 1.5 G, 100 mW
cm⁻²) of organic solar cells (OSC) prepared
according to Example 3 of the present disclosure

| | V [symbol] | J [symbol] (J [symbol] ) | FF | PCEₘₐₓ | PCE_{avg} |
|---|---|---|---|---|---|
| Structure of OSC | [V] | [mA cm−2] | [%] | [%] | [%] |
| ITO/PEDOT:PSS/ | 0.93 | 16.44(15.95) | 66.06 | 10.10 | 9.8 ± 0.3 |
| BHJ/Al | | | | | |
| ITO/PEDOT:PSS/ | 0.96 | 16.80(16.30) | 72.02 | 11.56 | 11.3 ± 0.3 |
| BHJ/PDINO/Al | | | | | |
| ITO/PEDOT:PSS-GO/ | 0.96 | 17.43(16.91) | 74.34 | 12.44 | 12.2 ± 0.2 |
| BHJ/PDINO-G/Al | | | | | |
| ITO/PEDOT:PSS-GO/ | 0.95 | 17.55(17.02) | 68.48 | 11.42 | 11.1 ± 0.3 |
| BHJ/PDINO-G/Ag | | | | | |
| ITO/PEDOT:PSS-GO/ | 0.95 | 15.84(15.36) | 68.51 | 10.31 | 9.7 ± 0.3 |
| BHJ/PDINO-G/Au | | | | | |

[symbol]

J [symbol] comes from EQE spectrum; and for brevity, BHJ is used instead of active layer. [symbol]
indicates data missing or illegible when filed

D. Influence of different doping proportions on photovoltaic devices

The influence of different graphene doping proportions in the PDINO-G cathode interface modification material on the photovoltaic property of the photovoltaic devices was systematically studied, as shown in Table 11.

TABLE 11
Influence of different graphene doping proportions
on photovoltaic property of photovoltaic devices

| Proportion | V [symbol] | J [symbol] | FF | PCE |
|---|---|---|---|---|
| of graphene | [V] | [mA cm⁻²] | [%] | [%] |
| 1% | 0.96 | 17.06 | 71.90 | 11.78 |
| 2% | 0.96 | 17.23 | 72.22 | 11.95 |
| 3% | 0.96 | 17.29 | 72.51 | 12.03 |
| 4% | 0.96 | 17.31 | 72.86 | 12.11 |
| 5% | 0.96 | 17.08 | 72.79 | 11.94 |
| 6% | 0.96 | 16.94 | 71.82 | 11.75 |
| 7% | 0.96 | 16.85 | 71.58 | 11.58 |
| 8% | 0.95 | 16.61 | 71.89 | 11.34 |
| 9% | 0.95 | 16.49 | 72.13 | 11.29 |
| 10% | 0.95 | 16.63 | 71.80 | 11.30 |
| 20% | 0.94 | 16.77 | 71.05 | 11.20 |

[symbol]

indicates data missing or illegible when filed

E. Measurement of device roughness

Roughness (RMS) was measured using an atomic force microscope, and the results were listed in Table 12.

TABLE 12
Roughness (RMS) of different OSCs

| Active layer | Structure of OSC | RMS (nm) |
|---|---|---|
| PTQ10:IDIC | ITO/PEDOT:PSS/BHJ | 2.41 |
| | ITO/PEDOT:PSS-GO/BHJ | 2.29 |
| | ITO/PEDOT:PSS/BHJ/PDINO | 2.17 |
| | ITO/PEDOT:PSS/BHJ/PDINO-G | 1.68 |

[symbol]

For brevity , BHJ is used instead of active layer. [symbol]
indicates data missing or illegible when filed

### Example 4

A. A cathode interfacial material modification composition comprising graphene and PDINO was prepared using the same method as that used in Example 1.
B. An organic solar cell was prepared using a method similar to that of Example 1, in which MO-IDIC-2F was used instead of IDIC-2F as the acceptor material, wherein PTQ10:MO-IDIC-2F was 1:1 wt.
C. Analysis of photovoltaic property
Table 13 lists the photovoltaic parameters of the devices having different structures.

The photovoltaic devices that do not use any cathode interface modification material have a relatively low photoelectric conversion efficiency (PCE), which is only 10.2% (open-circuit voltage (V_{OC})=0.87 V, short-circuit current (J_{SC})=17.50 mA cm⁻², and fill factor (FF)=67.50%). When a classical cathode interface modification material PDINO is inserted, the PCE is 11.9% (open-circuit voltage=0.88 V, short-circuit current=19.18 mA cm⁻², and fill factor=71.36%). When PDINO dispersed graphene PDINO-G is used as the cathode interface modification layer 104, the PCE of the device is increased to 13.1% (open-circuit voltage=0.89 V, short-circuit current=19.86 mA cm⁻², and fill factor=74.29%).

TABLE 13
Photovoltaic property data (AM 1.5 G, 100 mW
cm⁻²) of organic solar cells (OSC) prepared
according to Example 4 of the present disclosure

| | V [symbol] | J [symbol] (J [symbol] ) | FF | PCEₘₐₓ | PCE_{avg} |
|---|---|---|---|---|---|
| Structure of OSC | [V] | [mA cm⁻²] | [%] | [%] | [%] |
| ITO/PEDOT:PSS/ | 0.87 | 17.50(16.98) | 67.50 | 10.30 | 10.2 ± 0.1 |
| BHJ/Al | | | | | |
| ITO/PEDOT:PSS/ | 0.88 | 19.18(18.60) | 71.36 | 12.03 | 11.9 ± 0.3 |
| BHJ/PDINO/Al | | | | | |
| ITO/PEDOT:PSS-GO/ | 0.89 | 19.86(19.07) | 74.29 | 13.13 | 13.1 ± 0.2 |
| BHJ/PDINO-G/Al | | | | | |
| ITO/PEDOT:PSS-GO/ | 0.87 | 19.00(18.43) | 69.93 | 11.56 | 11.3 ± 0.3 |
| BHJ/PDINO-G/Ag | | | | | |
| ITO/PEDOT:PSS-GO/ | 0.87 | 18.24(17.69) | 68.19 | 10.82 | 10.5 ± 0.3 |
| BHJ/PDINO-G/Au | | | | | |

[symbol]

J [symbol] comes from EQE spectrum; and for brevity, BHJ is used instead of active layer. [symbol]
indicates data missing or illegible when filed

### Example 5

A. A cathode interfacial material modification composition comprising graphene and NDINO was prepared using a method similar to that of Example 1.
B. A ZnO precursor solution was prepared by dissolving 0.24 g of zinc acetate dihydrate (Zn(CH₃COO)₂.2H₂O, 99.9%, Aldrich) and 0.83 μL of ethanolamine (NH₂CH₂CH₂OH, 99.5%, Aldrich) in 3.00 ml of 2-methoxyethanol (CH₃OCH₂CH₂OH, 99.8%, J & K Scientific). A thin layer of ZnO was deposited by spin-coating a ZnO solution onto pre-cleaned ITO glass at 6000 rpm, which was then dried at 200° C. for 1 hour. A methanol solution of the NDINO-G cathode interface modification layer 104 having 5% graphene and having a concentration of 1.0 mg mL⁻¹ was then deposited on the ZnO layer at 3000 rpm, which was dried in air at 100° C. for 4 minutes. The substrate was then transferred to a nitrogen protected glove box, wherein a chloroform solution of PM6:Y6 (1:1.2, w/w) was spin-coated onto the interface-treated substrate as the active layer 103. Thereafter, the active layer 103 was annealed at 110° C. for 10 minutes for thermal annealing treatment of the device. 12 nm MoO₃ and 100 nm silver were then evaporated sequentially at a pressure of about 5.0×10⁻⁵ Pa. For a cell having a reverse structure, 100 nm metallic silver is generally evaporated as the anode 101 of the photovoltaic device, and 5-15 nm MoO₃ is evaporated at a low speed as the anode hole buffer layer of the cell before the evaporation of the metallic silver electrode. The evaporation speed of the anode hole buffer layer was 0.2 Å/s, and the evaporation speed of the metallic silver electrode was 3 Å/s. The resultant structure was (ITO/ZnO/NDINO-G (1 mg mL⁻¹ NDINO containing 5% graphene)/PM6:Y6/MoO₃/Ag).
C. Analysis of photovoltaic property

The reverse device comprising NDINO-G as the cathode interface modification layer 104 exhibited a PCE of 15.70% (V_{OC}=0.82 V, J_{SC}-25.12 mA cm⁻², and FF=76.20%). The testing result certified by National Institute of Metrology, China was PCE=15.50% (V_{OC}=0.81 V, J_{SC}=24.85 mA cm⁻², and FF=77.00%).

### Comparative Example 1

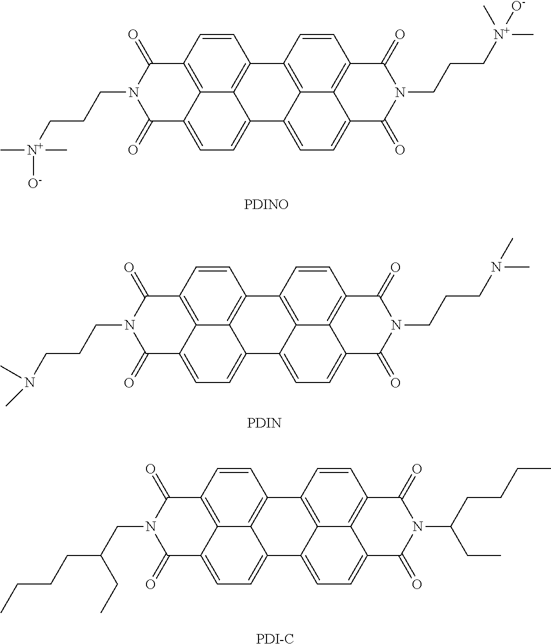

0.1 mg/ml of dispersants (PDINO, PDIN, and PDI-C) and 0.05 mg/ml of single-layer graphene were dissolved separately in o-dichlorobenzene, o-xylene and N,N-dimethylformamide (DMF). The mixtures were subjected to ultrasonic treatment in a 0° C. ice bath for 1 h, and were observed for experimental phenomenon after standing for a period of time.

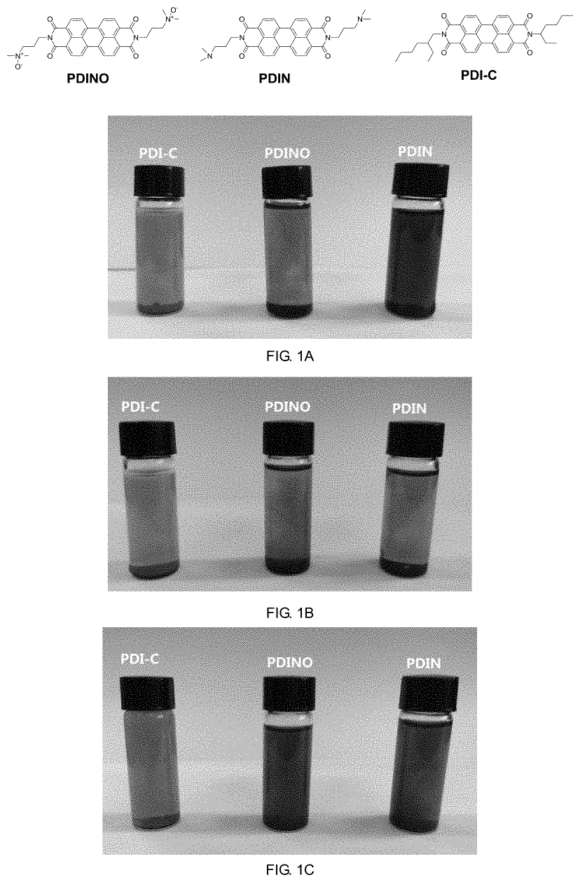

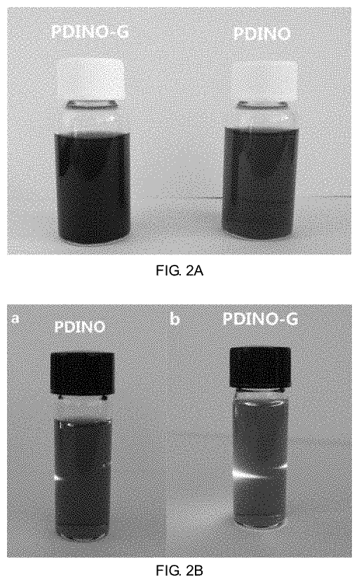

FIG. 1A: the solvent was o-dichlorobenzene, the standing time was 10 minutes, and obvious agglomeration and settlement were observed at the bottom.

FIG. 1B: the solvent was o-xylene, the standing time was 10 minutes, and almost all of the graphene dispersed by the three dispersants exhibited settlement and agglomeration at the bottom.

FIG. 1C: the solvent was N,N-dimethylformamide, the standing time was 10 minutes, PDINO dispersed graphene slightly exhibited agglomeration and settlement at the bottom, and PDIN dispersed graphene and PDI-C dispersed graphene exhibited obvious settlement and agglomeration at the bottom.

What is claimed is:

1. A cathode interface modification material composition, comprising:
(a) an alcohol solvent;
(b) an organic cathode interfacial material, wherein the organic cathode interfacial material is alcohol soluble, wherein the organic cathode interfacial material is dissolved in the alcohol solvent to form a solution of the organic cathode interfacial material; and
(c) a carbon nanomaterial, wherein the carbon nanomaterial is uniformly dispersed in the solution of the organic cathode interfacial material and has a maximum dimension of less than or equal to 5 μm.

2. The cathode interface modification material composition according to claim 1, wherein the alcohol solvent is selected from the group consisting of methanol, ethanol, propanol, isopropanol, n-butanol, isobutanol, tert-butanol, pentanol, isoamylol, hexanol, heptanol, octanol, nonanol, decanol and combinations thereof.

3. The cathode interface modification material composition according to claim 2, wherein the alcohol solvent is selected from the group consisting of methanol, ethanol, propanol, isopropanol and combinations thereof.

4. The cathode interface modification material composition according to claim 1, wherein the organic cathode interfacial material is selected from the group consisting of conjugated small molecules, conjugated polymers, non-conjugated materials and combinations thereof.

5. The cathode interface modification material composition according to claim 4, wherein the organic cathode interfacial material is selected from the group consisting of following (i), (ii), (iii), (iv) and combinations thereof:
(i) conjugated small molecules having following formulas: 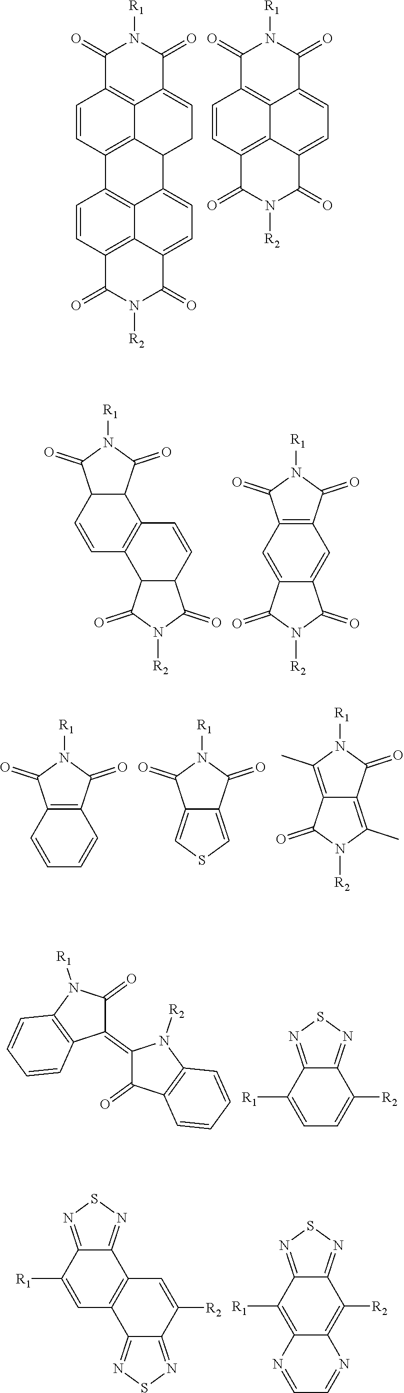 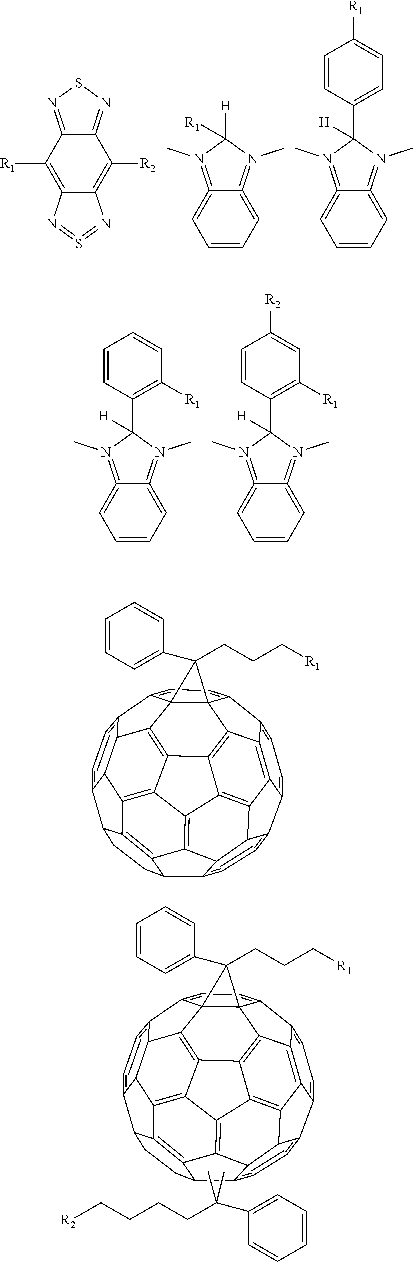 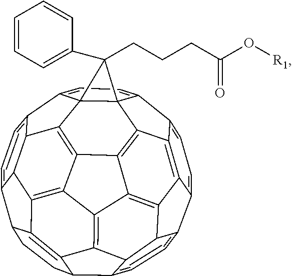
where R₁ and R₂ are each independently selected from the group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group;
(ii) A-D-A type conjugated small molecules having following formula: 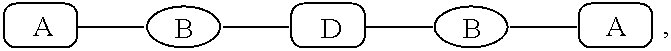
where A is a conjugated unit having an electron-withdrawing property, and is one or more selected from the group consisting of following structures: 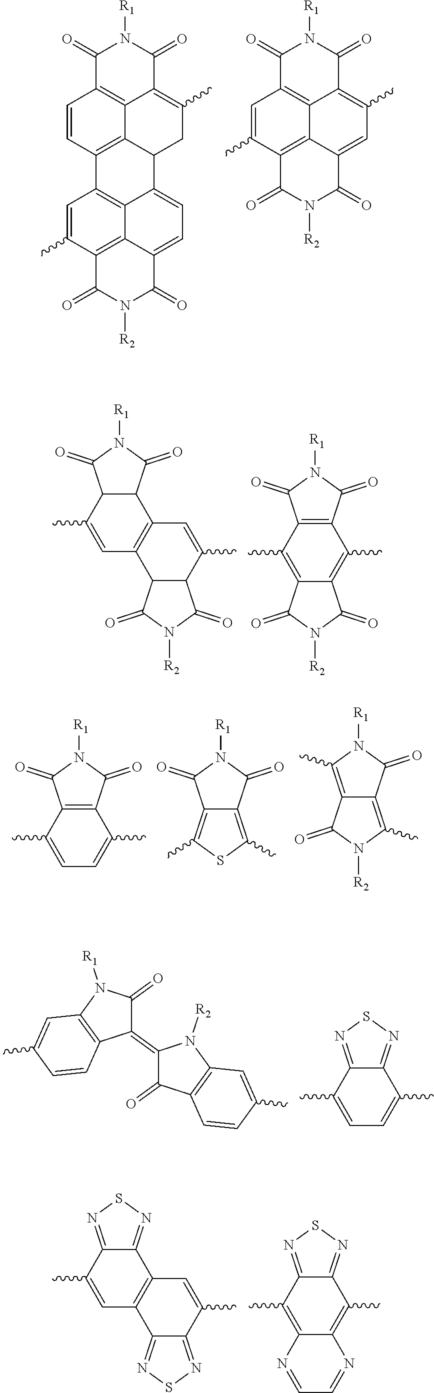 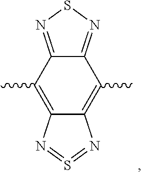
where R₁ and R₂ are independently selected from C₁₋₂₀ linear or branched alkyl groups, or C₃₋₂₀ cycloalkyl groups; and one or more of carbon atoms in R₁ and R₂ is/are independently substituted by an oxo group, an alkenyl group, an alkynyl group, an aryl group, a hydroxy group, an amino group, a carbonyl group, a carboxyl group, an ester group, a cyano group, a nitro group, a fluorine atom, a chlorine atom, a bromine atom or an iodine atom;
B is a bridge bond connecting A and D conjugated units, and is one or more selected from the group consisting of following structures: 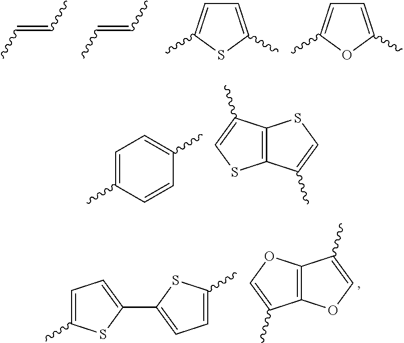
D is a conjugated unit having an electron-donating property, and is one or more selected from the group consisting of following structures: 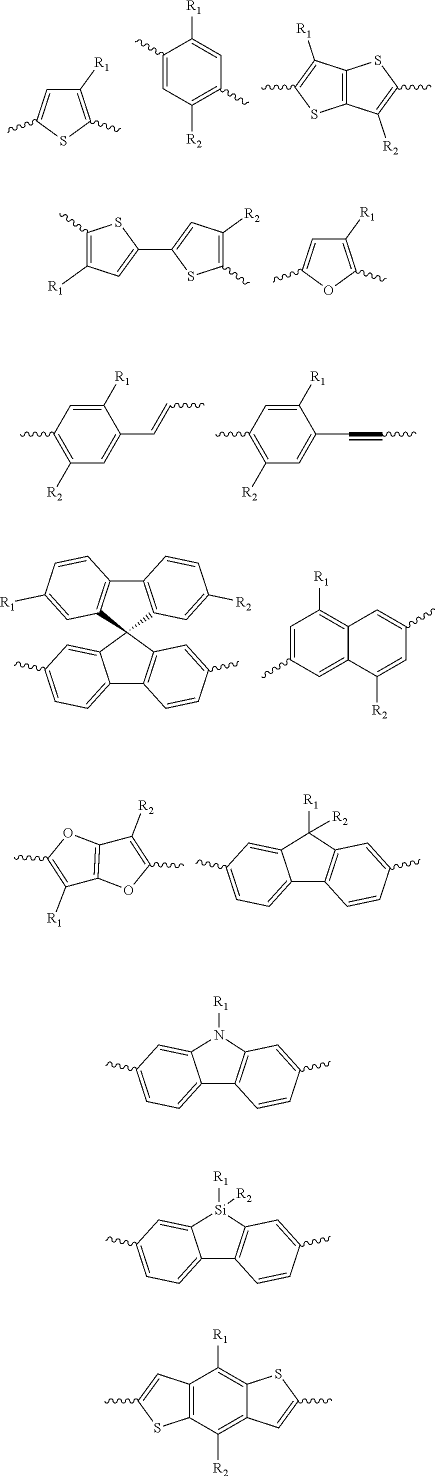 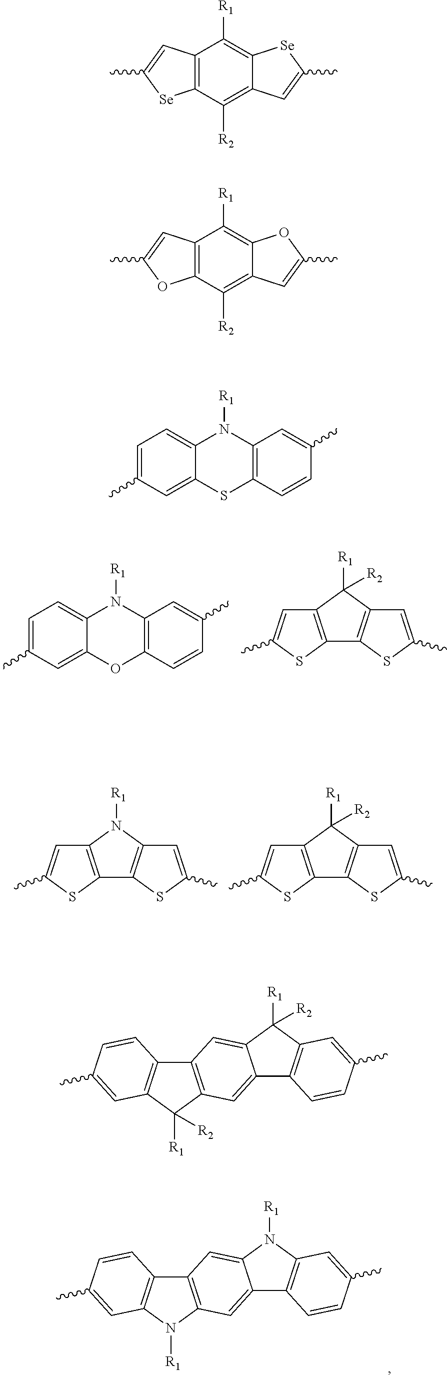
where R₁ and R₂ are independently selected from the group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group;
(iii) conjugated polymers having following formula: 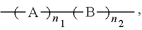
where n₁=1, 2, 3, 4 . . . , and n₂=0, 1, 2, 3 . . . ;
A and B are independently one or more selected from the group consisting of following structures: 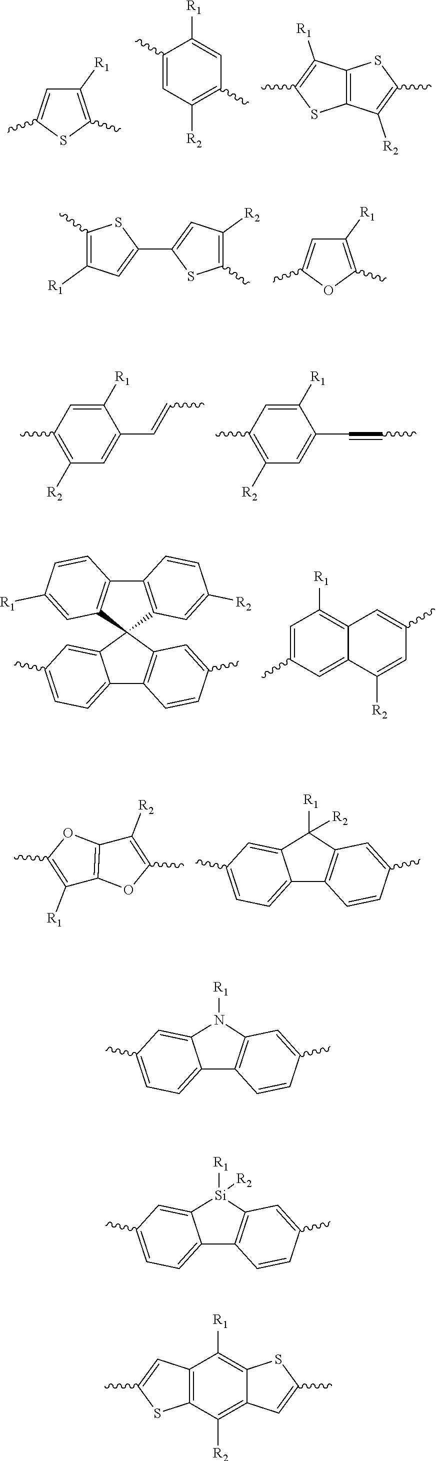 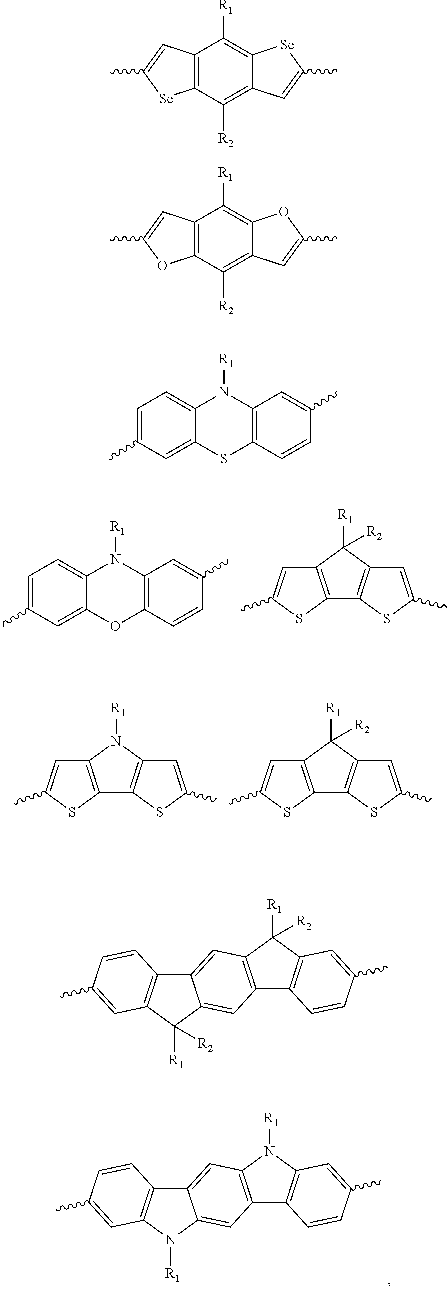 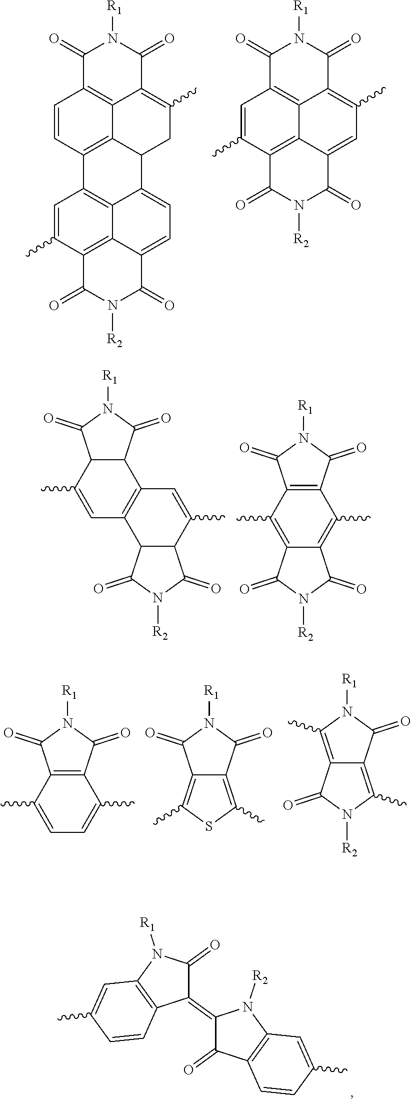
where R₁ and R₂ are independently selected from the group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group; and
(iv) non-conjugated materials having one of following formulas: 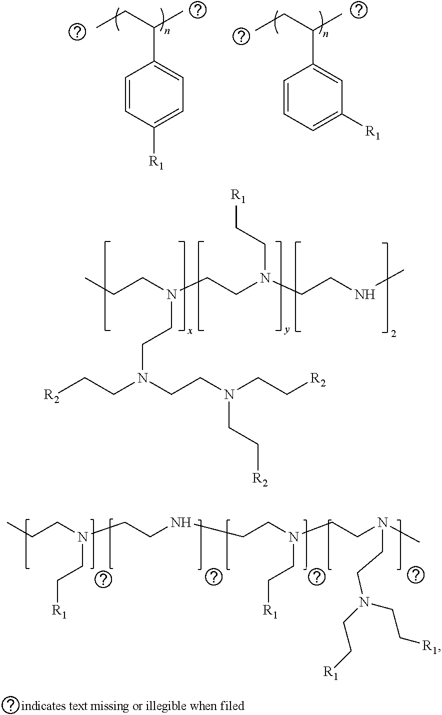
where R₁ and R₂ are independently selected from the group consisting of an amine group, a quaternary ammonium salt, a nitrile group, a carboxyl group, a carboxylic acid salt, a sulfonic acid group, a phosphoric acid group, a phosphate ester group, a hydroxyl group, a triethylene glycol group, an epoxy group and an ester group.

6. The cathode interface modification material composition according to claim 1, wherein the organic cathode interfacial material has one or more selected from the group consisting of following structures:

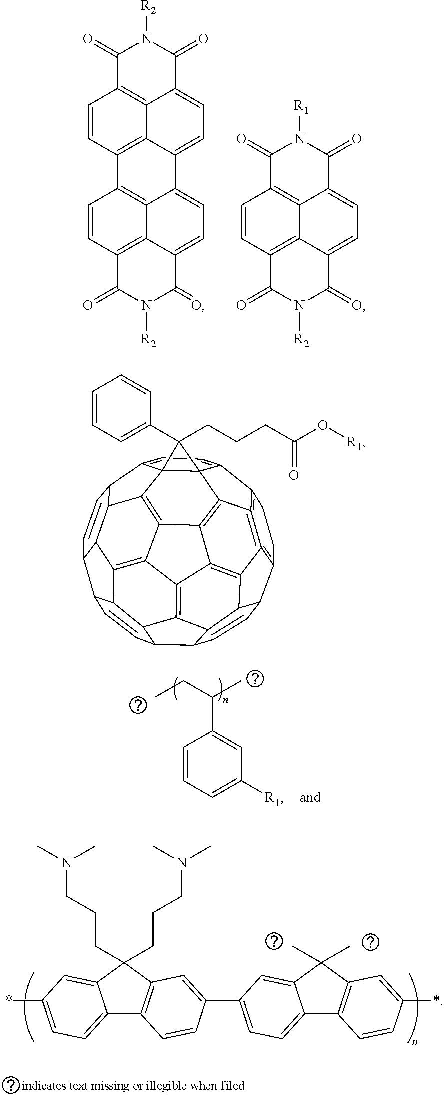

7. The cathode interface modification material composition according to claim 6, wherein the organic cathode interfacial material has the structure of:

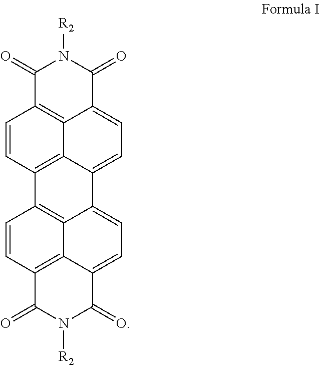

8. The cathode interface modification material composition according to claim 7, wherein the organic cathode interfacial material is perylene tetracarboxylic acid-bis(N,N-dimethylpropane-1-amine oxide)imide.

9. The cathode interface modification material composition according to claim 1, wherein the carbon nanomaterial is selected from the group consisting of graphene quantum dots, single- or multi-layer graphene, heteroatom-doped graphene, single-walled carbon nanotubes, few-walled carbon nanotubes, multi-walled carbon nanotubes, heteroatom-doped carbon nanotubes and combinations thereof.

10. The cathode interface modification material composition according to claim 9, wherein the carbon nanomaterial is single or multi-layer graphene.

11. The cathode interface modification material composition according to claim 1, wherein the organic cathode interfacial material has a negative surface adsorption energy for the carbon nanomaterial.

12. The cathode interface modification material composition according to claim 11, wherein the organic cathode interfacial material has a surface adsorption energy of less than or equal to 3.510 for the carbon nanomaterial.

13. A cathode interface modification layer, comprising an organic cathode interfacial material and a carbon nanomaterial uniformly dispersed in the organic cathode interfacial material, wherein the carbon nanomaterial has a sheet diameter of less than or equal to 5 μm.

14. The cathode interface modification layer according to claim 13, wherein the organic cathode interfacial material is as claimed in claim 4.

15. The cathode interface modification layer according to claim 13, wherein the carbon nanomaterial is selected from the group consisting of graphene quantum dots, single- or multi-layer graphene, heteroatom-doped graphene, single-walled carbon nanotubes, few-walled carbon nanotubes, multi-walled carbon nanotubes, heteroatom-doped carbon nanotubes, and combinations thereof.

16. The cathode interface modification layer according to claim 15, wherein the carbon nanomaterial is single or multi-layer graphene.

17. An organic photoelectric device, comprising the cathode interface modification layer according to claim 13.

18. The organic photoelectric device according to claim 17, wherein the organic photoelectric device is an organic solar cell, an organic light emitting diode, a perovskite solar cell, a photodetector or a super capacitor.

19. The organic photoelectric device according to claim 18, wherein the organic photoelectric device comprises:
a cathode,
the cathode interface modification layer, disposed on the cathode,
an anode, and
an active layer, disposed between the cathode interface modification layer and the anode.

20. The organic photoelectric device according to claim 19, further comprising an anode interface layer, which is disposed between the anode and the active layer.
